(19) United States
(12) Patent Application Publication
(10) Pub. No.: US 2024/0381753 A1
(43) Pub. Date: Nov. 14, 2024

(54) FABRICATING SOLAR CELL DEVICES TO REDUCE ACTIVE LAYER DAMAGE

(71) Applicant: Applied Materials, Inc., Santa Clara, CA (US)

(72) Inventors: Yongkee Chae, San Ramon, CA (US); Xun Li, Sunnyvale, CA (US); Jun-Nan Liu, Taichung City (TW); Shinobu Abe, Osaka (JP); Cheng-Pei Ouyang, Gilroy, CA (US); Su-Ho Cho, Santa Clara, CA (US); Yong Jin Kim, Albany, CA (US); Thomas Werner Zilbauer, Gauting (DE)

(21) Appl. No.: 18/649,723

(22) Filed: Apr. 29, 2024

Related U.S. Application Data
(60) Provisional application No. 63/464,983, filed on May 9, 2023.
(60) Provisional application No. 63/467,028, filed on May 17, 2023.

(51) Int. Cl. H10K 71/16; H10K 30/40; H10K 30/57; H10K 30/85

(52) U.S. Cl. CPC H10K 71/16; H10K 30/40; H10K 30/57; H10K 30/85

(57) ABSTRACT

A method includes obtaining a base structure of a tandem solar cell device and forming a transparent conductive oxide (TCO) layer on the base structure using a low damage sputter deposition (LDSD) process. The LDSD process includes a rotary facing sputter deposition process.

### CROSS-REFERENCE TO RELATED APPLICATION(S)

The present application claims priority to U.S. Provisional Patent Application No. 63/464,983, filed on May 9, 2023 and entitled “FABRICATING TANDEM SOLAR CELL DEVICES TO REDUCE ACTIVE LAYER DAMAGE”, and to U.S. Provisional Patent Application No. 63/467,028, filed on May 17, 2023 and entitled “FABRICATING SOLAR CELL DEVICES TO REDUCE ACTIVE LAYER DAMAGE”, the entire contents of which are hereby incorporated by reference herein.

### TECHNICAL FIELD

Embodiments of the present disclosure relate to electronic device fabrication generally. Particularly, embodiments of the present disclosure relate to fabricating solar cell devices to reduce active layer damage.

### BACKGROUND

Solar cell devices are devices that convert sunlight into energy by harnessing the photoelectric effect. Solar cells can be made of semiconducting materials that absorb photons from sunlight and use them to create an electric current. Solar cell devices are commonly used in solar panels, which are used to generate electricity from sunlight for homes, businesses, and other applications.

### SUMMARY

According to embodiments described herein is a method. The method includes obtaining a base structure of a tandem solar cell device, and forming a transparent conductive oxide (TCO) layer on the base structure using a low damage sputter deposition (LDSD) process. The LDSD process includes a rotatable facing target sputtering (RFTS) process.

According to embodiments described herein is a method. The method includes obtaining a base structure of a solar cell device, forming a layer on the base structure using a sputter deposition process, and completing fabrication of the solar cell device. Forming the layer on the base structure using the sputter deposition process includes directing first sputter material from a first rotary target with a facing magnet yoke position towards a second rotary target and directing second sputter material from the second rotary target with a facing magnet yoke position towards the first rotary target.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a block diagram of an example portion of an electronic device including a tandem solar cell device, in accordance with some embodiments.

FIG. 2A is a block diagram an example portion of a tandem solar cell device, in accordance with some embodiments.

FIG. 2B is a block diagram an example portion of a solar cell device, in accordance with some embodiments.

FIG. 3 is a block diagram of an example portion of a tandem solar cell device, in accordance with some embodiments.

FIG. 4A is a block diagram of an example tandem solar cell device, in accordance with some embodiments.

FIG. 4B is a block diagram of an example solar cell device, in accordance with some embodiments.

FIGS. 5A-5F are diagrams of systems for fabricating tandem solar cell devices to reduce active layer damage, in accordance with some embodiments.

FIGS. 6A-6B are flowcharts of methods for fabricating tandem solar cell devices to reduce active layer damage, in accordance with some embodiments.

FIGS. 7A-7I are block diagrams illustrating cross-sectional views during the fabrication a tandem solar cell device, in accordance with some embodiments.

FIGS. 8A-8D are diagrams illustrating the fabrication of a tandem solar cell device to reduce active layer damage, in accordance with some embodiments.

FIG. 9 is a diagram of a system for fabricating tandem solar cell devices to reduce active layer damage, in accordance with some embodiments.

FIGS. 10A-10B are flowcharts of methods for fabricating tandem solar cell devices to reduce active layer damage, in accordance with some embodiments.

FIG. 11 is a diagram of an example device with device-level encapsulation, in accordance with some embodiments.

FIG. 12 is a diagram of an example module of tandem solar cell devices with device-level encapsulation, in accordance with some embodiments.

FIG. 13 is a diagram of an example module of tandem solar cell devices with device-level encapsulation and module-level encapsulation, in accordance with some embodiments.

FIG. 14 is a block diagram of an example computer system in which implementations of the present disclosure may operate.

### DETAILED DESCRIPTION

Embodiments described herein relate to fabricating solar cell devices to reduce active layer damage. In some implementations, a solar cell device is a tandem solar cell device. A tandem solar cell device is a device including a stack of at least two solar cells. Each solar cell of the tandem solar cell device can be designed to capture a different portion of the solar spectrum, allowing for a higher overall efficiency as compared to single-cell solar cell devices. The top solar cell can be made of a semiconductor material with a wider bandgap, allowing it to capture photons having wavelengths from the blue end of the electromagnetic spectrum (e.g., having wavelengths between about 380 nanometers (nm) to about 500 nm). The bottom sub-cell can be made of a semiconductor material with a narrower bandgap, allowing it to capture photons having wavelengths from the red end of the electromagnetic spectrum (e.g., having wavelengths between about 625 nm to about 740 nm).

In some embodiments, a tandem solar cell device is a two-cell device including a first solar cell and a second solar cell disposed on the first solar cell. For example, the first solar cell can be a bottom solar cell and the second solar cell can be a top solar cell. A first set of electrodes can be formed on the first solar cell and a second set of electrodes can be formed on the second solar cell. Each electrode can be formed from any suitable material in accordance with embodiments described herein. For example, the first set of electrodes and the second set of electrodes can include silver (Ag) electrodes.

In some embodiments, the tandem solar cell device further includes a recombination layer disposed between the first solar cell and the second solar cell to facilitate recombination of electrons and holes. Recombination between an electron and a hole occurs when the electron and the hole recombine with each other instead of being collected at the respective electrodes to generate electrical current. In some embodiments, the recombination layer includes a transparent conductive oxide (TCO) layer. TCOs are materials that can conduct electricity while remaining optically transparent. TCOs can be formed from a base material including a metal oxide, such as zinc oxide (ZnO), tin oxide (SnO₂), etc., that have been doped with impurities such as Sn, indium (In), etc., to create free electrons that enable electricity conduction. Examples of TCOs include indium zinc oxide (IZO), indium tin oxide (ITO), indium cerium oxide (ICO), or aluminum-doped zinc oxide (AZO), etc. The doping process does not significantly affect the optical properties of the base material, and thus maintains their transparency properties. As a result, TCOs can transmit light in various regions of the electromagnetic spectrum (e.g., visible and near-infrared regions), making them useful for electronic device applications where transparency may be advantageous. For example, TCOs can be used in the fabrication of various types of electronic devices, such as touch screens, flat panel displays, photovoltaic devices (e.g., solar cells and image sensors), lighting devices, etc. In addition to their optical and electrical properties, TCOs can also exhibit high chemical stability and durability, which makes them suitable for use in harsh environments.

In some embodiments, the recombination layer includes at least one polycrystalline material. A polycrystalline material is a material including multiple crystal grains (in contrast to a monocrystalline material). In some embodiments, a polycrystalline material is a nanocrystalline material. A nanocrystalline material is a polycrystalline material including individual crystal grains having a size on the scale of nanometers. More specifically, a polycrystalline material can be a doped (e.g., heavily doped) polycrystalline material. For example, a polycrystalline material can be a p-type doped polycrystalline material or an n-type doped polycrystalline material. In some embodiments, the recombination layer includes at least one polycrystalline silicon (Si) material. For example, the recombination layer can include at least one p-type doped polycrystalline Si material, at least one n-type doped polycrystalline Si material, etc.

In some embodiments, the recombination layer includes at least two polycrystalline materials. More specifically, the recombination layer can include a p-type doped (or heavily doped) polycrystalline material and an n-type doped (or heavily doped) polycrystalline material. For example, the recombination layer can include a p-type doped polycrystalline Si material and an n-type doped polycrystalline Si material.

In some embodiments, the first solar cell is a heterojunction (HJT) solar cell. More specifically, an HJT solar cell can include a stack of alternating semiconductor layers of a semiconductor material disposed on a TCO layer. An HJT interface is defined at the boundary region where a respective pair of semiconductor layers of the stack meet, which can form an electric field that facilitates the separation and collection of electron-hole pairs. The first set of electrodes can be disposed on the TCO layer of the HJT solar cell.

Each semiconductor layer of the stack is formed from a different type of semiconductor material. For example, an HJT solar cell can include a first semiconductor layer including a doped semiconductor material. The first semiconductor layer can be disposed on a second semiconductor layer including an intrinsic semiconductor material. The second semiconductor layer can be disposed on a third semiconductor layer including a doped semiconductor material. The third semiconductor layer can be disposed on a fourth semiconductor layer including an intrinsic semiconductor material. The fourth semiconductor layer can be disposed on a fifth semiconductor layer including a doped semiconductor material. The fifth semiconductor layer can be disposed on the TCO layer of the HJT solar cell. In some embodiments, the first semiconductor layer and the third semiconductor layer each include an n-type semiconductor material and the fifth layer includes a p-type semiconductor material. In some embodiments, the first semiconductor layer and the third semiconductor layer each include a p-type semiconductor material and the fifth layer includes an n-type semiconductor material.

In some embodiments, each semiconductor layer of the stack includes silicon (Si). For example, the first semiconductor layer can be a first amorphous Si (a-Si) layer, the second semiconductor layer can be a first intrinsic Si (i-Si) layer, the third semiconductor layer can be a crystalline Si (c-Si) layer (e.g., monocrystalline Si or polycrystalline Si), the fourth semiconductor layer can be a second i-Si layer, and the fifth semiconductor layer can be a second a-Si layer. In some embodiments, the first a-Si layer and the c-Si layer are each n-type layers (i.e., n-a-Si and n-c-Si) and the second a-Si layer is a p-type layer (i.e., p-a-Si). In some embodiments, the first a-Si layer and the c-Si layer are each p-type layers (i.e., p-a-Si and p-c-Si) and the second a-Si layer is an n-type layer (i.e., n-a-Si).

In some embodiments, the second solar cell includes a TCO layer disposed on a stack including an electron transport layer (ETL) disposed on an active layer. The function of the ETL is to collect electrons that are generated when sunlight is absorbed by the active layer, and transport the electrons to the electrode of the solar cell. Thus, the ETL can improve the efficiency of electron transport from the active layer to an external circuit. The ETL can include a material selected to enable electron transport. Examples of materials that can be used to form ETLs include titanium dioxide (TiO2), ZnO, SnO₂, etc. In some embodiments, the ETL functions as a barrier layer to prevent the diffusion of impurities between the electrode and the active layer, which can improve stability and longevity of the solar cell. The second set of electrodes can be disposed on the TCO layer of the second solar cell.

In some embodiments, the second solar cell is a perovskite solar cell. More specifically, the active layer of the solar cell can include a perovskite layer including a perovskite material, and the ETL can be disposed on the perovskite layer. A perovskite material has a crystal structure with the chemical formula ABX₃, where A and B are cations (i.e., positively charged ions) and X is an anion (i.e., negatively charged ion). A perovskite material can have a set of properties (e.g., bandgap) that enables absorption of solar radiation and generation of a larger number of electron-hole pairs, which can be separated and collected to generate an electrical current. One example of a perovskite material is methylammonium lead triiodide (CH₃NH₃PbI₃). The active layer can be disposed on a hole transport layer (HTL) that can extract and transport holes (i.e., positive charges). The HTL can be formed from a material that has high hole mobility to enable transport of holes. For example, the HTL can be formed from a nickel oxide (e.g., NiOₓ), a molybdenum oxide (MoOₓ), a vanadium oxide (VOₓ), a tungsten oxide (WOₓ), a copper oxide (CuOₓ or CuₓO), a copper gallium oxide (CuGaOₓ), a copper aluminum oxide (CuAlOₓ), a copper chromium oxide (e.g., CuCrOₓ), ZnO, an aluminum nickel oxide (Al_{y}Ni_{1-y}Oₓ), spiro-OMeTAD (2,2′,7,7′-tetrakis(N,N-di-p-methoxyphenylamine)-9,9′-spirobifluorene), poly(3,4-ethylenedioxythiophene) (PEDOT), etc. Accordingly, a tandem solar cell device can be a perovskite/HJT tandem solar cell device.

In some embodiments, the first solar cell includes a TCO layer disposed on a stack including an ETL disposed on an active layer. For example, the first solar cell can be a perovskite solar cell. Accordingly, the tandem solar cell device can be a perovskite/perovskite tandem solar cell device.

In some embodiments, the tandem solar cell device is a triple-cell device. More specifically, the tandem solar cell can include a first solar cell, a second solar cell disposed on the first solar cell, and a third solar cell disposed on the second solar cell. For example, the first solar cell can be an HJT solar cell, and the second and third solar cell can each include a TCO layer disposed on a stack including an ETL disposed on an active layer (e.g., a perovskite solar cell). Accordingly, the tandem solar cell device can be a perovskite/perovskite/HJT tandem solar cell device.

A TCO layer of a solar cell device can be deposited by using a sputter deposition process during the fabrication of the solar cell device. For example, a TCO layer can be deposited on an ETL of a solar cell (e.g., perovskite solar cell) by using a sputter deposition process during the fabrication of the solar cell. As another example, a TCO layer can be deposited on a stack of alternating semiconductor layers of a solar cell (e.g., HJT solar cell) by using a sputter deposition process during the fabrication of the solar cell. As yet another example, a recombination layer including a TCO layer can be deposited on the second solar cell device by using a sputter deposition process during the fabrication of the tandem solar cell device (and then the first solar cell can be formed on the recombination layer).

Sputter deposition, or sputtering, is a physical vapor deposition (PVD) technique for deposition of a material on a substrate. Sputtering involves discharging material from a target over a substrate by using energetic ions or gas in an inert gas atmosphere. Sputtering lead to the bombardment of the substrate with particles (e.g., ion bombardment and/or electron bombardment) and/or ultraviolet (UV) irradiation. This, in turn, can result in damage to the underlying layers upon which the TCO layer is being formed due to particle bombardment and/or UV irradiation, which can lead to solar cell performance degradation. For example, the underlying layers can include a stack including an ETL of a solar cell (e.g., perovskite solar cell) and the TCO layer can be formed on the stack. As another example, the underlying layers can include a stack of alternating semiconductor layers (e.g., HJT solar cell) and the TCO layer can be formed on the stack (e.g., the fifth semiconductor layer). As yet another example, the underlying layers can include a first solar cell of a tandem solar cell device (e.g., an HJT solar cell), and the TCO layer can correspond to a recombination layer formed on the first solar cell (e.g., the first semiconductor layer).

To address the damage caused by particle bombardment during sputter deposition processes to form TCO layers, some solar cells can utilize a buffer layer that protects the underlying layers during the deposition of the TCO layer (e.g., the buffer layer can be formed on the ETL of a solar cell). For example, the buffer layer can include SnO₂. However, the buffer layer can remain after the formation of the TCO layer, which can contribute to parasitic absorption and can generate optical loss by blocking light. Accordingly, the use of buffer layers to protect underlying layers during the formation of TCO layers using sputter deposition processes can negatively impact solar cell device performance.

To address these and other drawbacks, embodiments described herein provide for methods of fabricating solar cell devices to reduce active layer damage. Embodiments described herein can eliminate the use of a buffer layer to protect underlying layers of a solar cell device during TCO layer formation, such as an ETL and active layer of a solar cell. Accordingly, in embodiments a buffer layer (e.g., of SnO₂) is omitted.

In some embodiments, a solar cell device is a tandem solar cell device. A tandem solar cell device described herein can include any number of solar cells in accordance with embodiments described herein. In some embodiments, a tandem solar cell device is a two-cell device including a first solar cell and a second solar cell disposed on the first solar cell. A recombination layer can be disposed between the first solar cell and the second solar cell. For example, a tandem solar cell device can be a perovskite/HJT tandem solar cell device, a perovskite/perovskite tandem solar cell device, etc. In some embodiments, a tandem solar cell device is a triple cell device including a first solar cell, a second solar cell disposed on the first solar cell, and a third solar cell disposed on the second solar cell. For example, a tandem solar cell device can be a perovskite/perovskite/HJT tandem solar cell device.

For example, fabricating a tandem solar cell device can include obtaining a base structure of a tandem solar cell device, and forming a TCO layer on the base structure. In some embodiments, obtaining the base structure includes receiving the base structure within a processing chamber capable of forming a TCO layer. For example, the base structure can be placed on a carrier (e.g., a hollow carrier) to hold the base structure and loaded into the processing chamber. In some embodiments, a robot apparatus loads the base structure (e.g., the carrier holding the base structure) within the processing chamber.

In some embodiments, the base structure includes a stack of layers including an ETL of a solar cell of a solar cell device. For example, the solar cell can be a perovskite solar cell. A TCO layer can be formed on the stack of layers including the ETL using an LDSD process. In some embodiments, the base structure includes a stack of alternating semiconductor layers of a solar cell of a solar cell device. For example, the solar cell can be an HJT solar cell. A TCO layer can be formed on the stack of alternating semiconductor layers using an LDSD process. In some embodiments, the base structure includes a first solar cell of a tandem solar cell device. For example, the first solar cell can be an HJT solar cell. A TCO layer corresponding to a recombination layer can be formed on the first solar cell. A second solar cell of the tandem solar cell device (e.g., a perovskite solar cell) can then be formed on the recombination layer.

To further reduce sputtering damage due to particle bombardment, embodiments described herein can be used to form at least one layer of a solar cell device using a low damage sputter deposition (LDSD) process performed by an LDSD system. For example, an LDSD process can be used to form a TCO layer on a base structure of a solar cell device. The LDSD process can minimize damage caused by other deposition (e.g., sputtering) processes due to, e.g., particle bombardment and/or UV irradiation. Accordingly, an LDSD process can suppress or reduce bombardment of high-energy particles (e.g., such as sputter-emitted atoms, negative oxygen ions, UV radiation, etc.) onto a surface on which a layer is being deposited. For example, if the base structure includes a stack of layers including an ETL of a solar cell of a solar cell device (e.g., a perovskite solar cell), then performing the LDSD process to form a TCO layer can include forming the TCO layer on the stack of layers (e.g., on the ETL). As another example, if the base structure includes a stack of alternating semiconductor layers of a solar cell of a solar cell device (e.g., an HJT solar cell), then performing the LDSD process to form a TCO layer can include forming the TCO layer on the stack of alternating semiconductor layers (e.g., on the fifth semiconductor layer). As yet another example, if the base structure includes a first solar cell of a tandem solar cell device (e.g., an HJT solar cell), then performing the LDSD process to form a TCO layer can include forming the TCO layer as a recombination layer on the first solar cell.

An LDSD system is a sputter deposition system that performs an LDSD process by using cathodes to provide plasma confinement regions that are not directed straight toward the substrate. In some embodiments, an LDSD system is a magnetron sputtering system. Magnetron sputtering can achieve high deposition rates confining the sputter plasma in a plasma confinement region adjacent to a surface of a rotary target that is to be sputtered (e.g., cylindrical target or dog-bone target). This enhances the probability of ionizing the gas molecules typically by several orders of magnitude, such that the deposition rate can be significantly increased.

A magnetron sputtering system can include a magnet assembly used for confining sputter plasma in a predetermined region. The magnet assembly can be positioned within a rotary target. By arranging the magnet assembly within the rotary target the free electrons above the rotary target surface are forced to move within the magnetic field and cannot escape. A “closed” plasma racetrack extends along a closed path or track on a surface of the rotary target, such that the electrons of the plasma cannot escape and cannot leave the plasma racetrack at an open end of the plasma confinement region because the racetrack is closed. More specifically, the magnet assembly generates a magnetic field with magnetic field lines around which the free electrons of the plasma helically circulate while remaining in the area that is defined by the plasma racetrack because the plasma racetrack is closed. The form of the closed plasma racetrack on the rotary target surface is defined by a closed path along which the magnets of the magnet assembly extend inside the rotary target.

Some magnetic assemblies can provide a closed plasma racetrack on a single side of the magnetron sputter cathode that is typically directed directly toward the substrate. Alternatively, two separate closed plasma racetracks may be generated on two opposite sides of the magnetron sputter cathode that are directed toward two different substrates, e.g., for dual-side sputtering. Also in the latter case, each of the two separate closed plasma racetracks is arranged on only one single side of the magnetron sputter cathode. Such a magnet assembly typically includes a first magnet that is surrounded by a second magnet arranged at a close distance thereto, such that a closed plasma racetrack (a so-called “dual racetrack”) is generated in an area in front of the magnet assembly, and is also referred to herein as a “front sputter magnet assembly”. A front sputter magnet assembly can enable high deposition rates but may entail a risk that sensitive substrates are negatively affected due to a high energy input per unit area toward the substrate.

For example, performing an LDSD process can include moving a carrier about a sputtering region to form a layer on a base structure (e.g., forming a TCO layer on the ETL). Various parameters of the LDSD process can be optimized to form a layer to achieve layer properties while avoiding or minimizing the damage of underlying layers (e.g., thickness, sheet resistance, adhesion, stress and/or roughness). Examples of such parameters includes magnet angle, target-to-base structure distance, gas flow mixture, pressure, magnet yoke direction, aperture openings, etc. The LDSD process can be a low temperature process. In some embodiments, the LDSD process is performed at a temperature of less than or equal to about 80° C. In some embodiments, the LDSD process is performed at a temperature of less than or equal to about 60° C. In some embodiments, the LDSD process is performed at a temperature of less than or equal to about 50° C. In some embodiments, the LDSD process is performed at about room temperature.

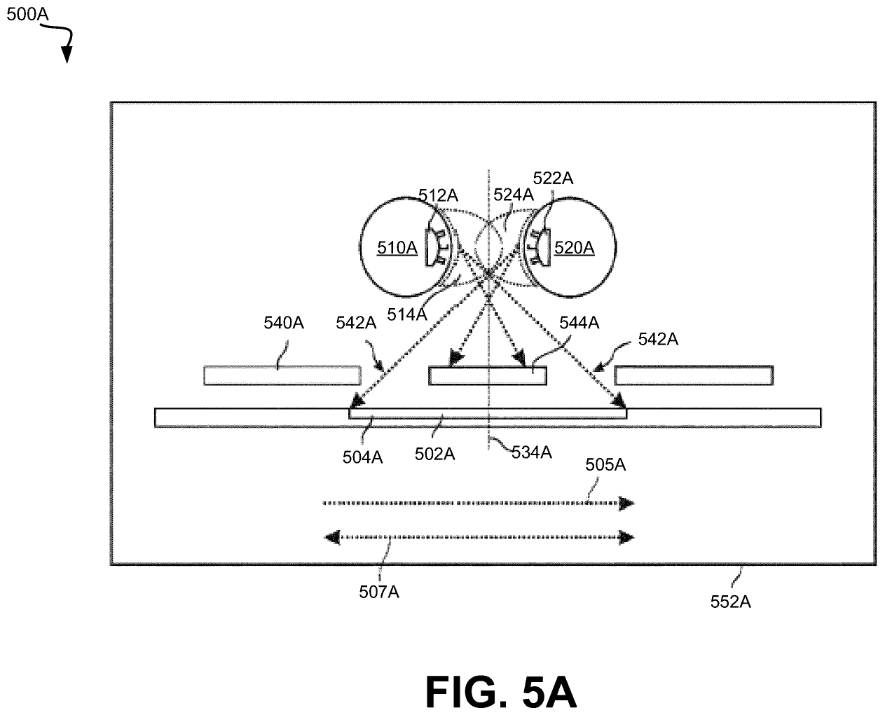

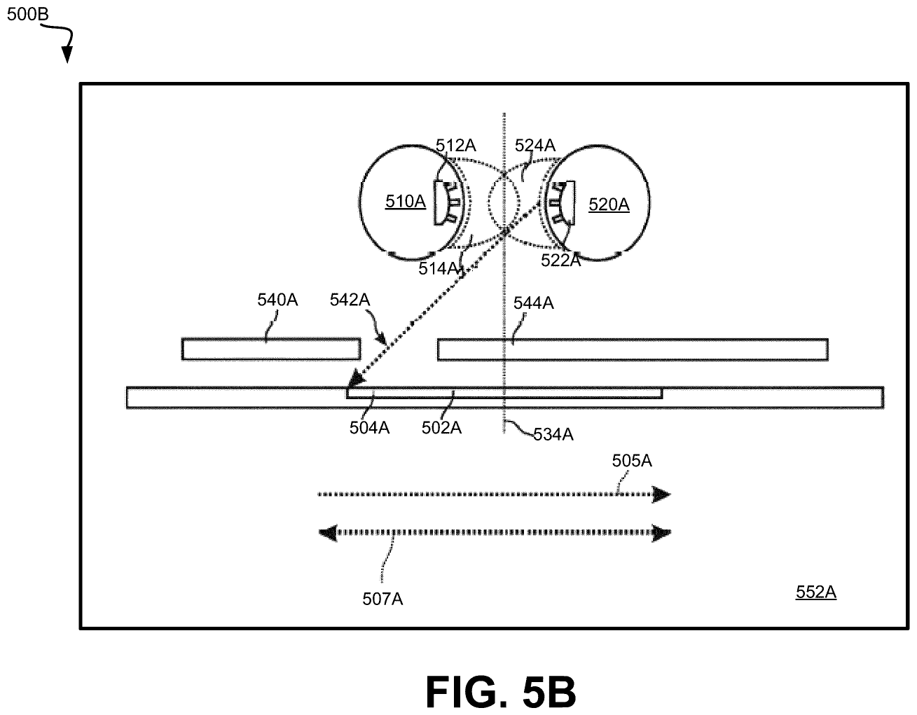

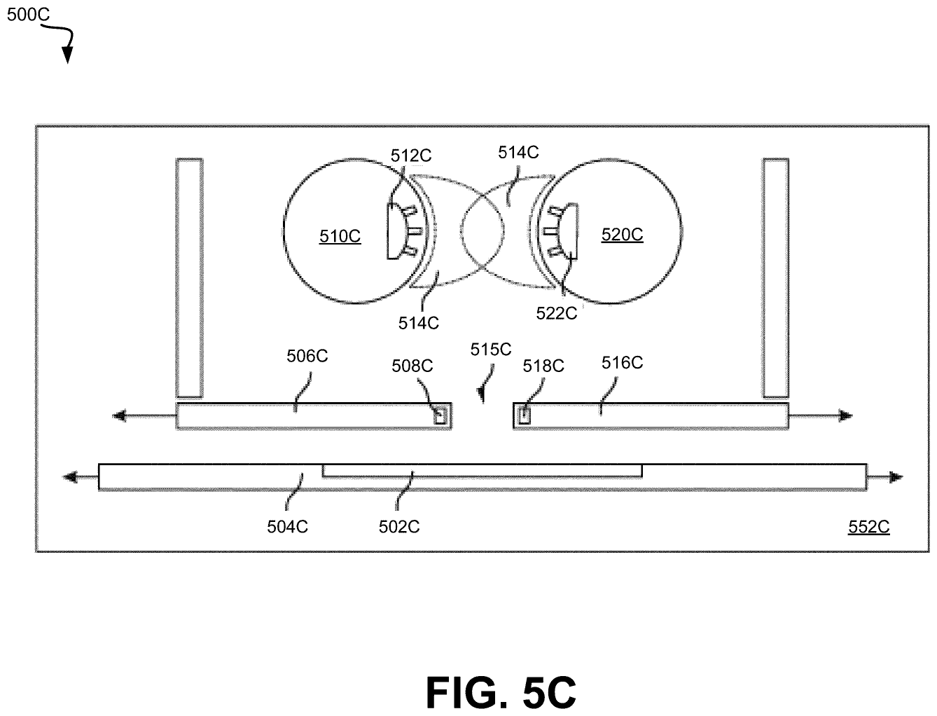

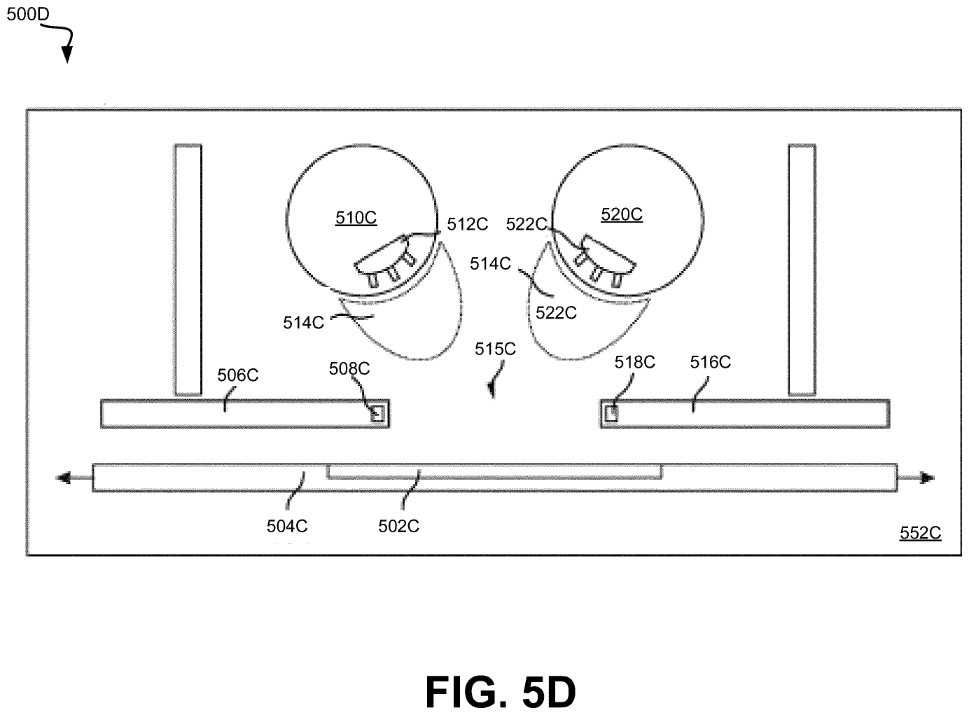

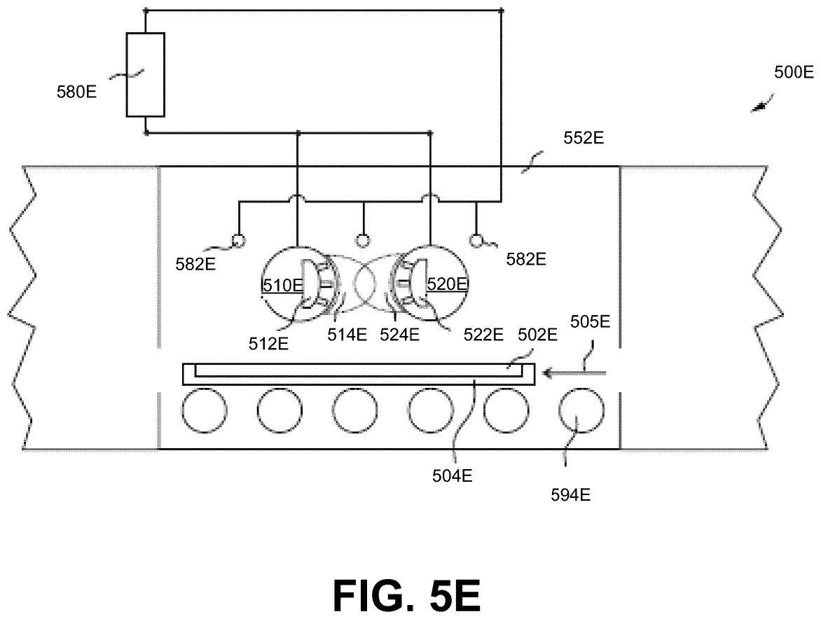

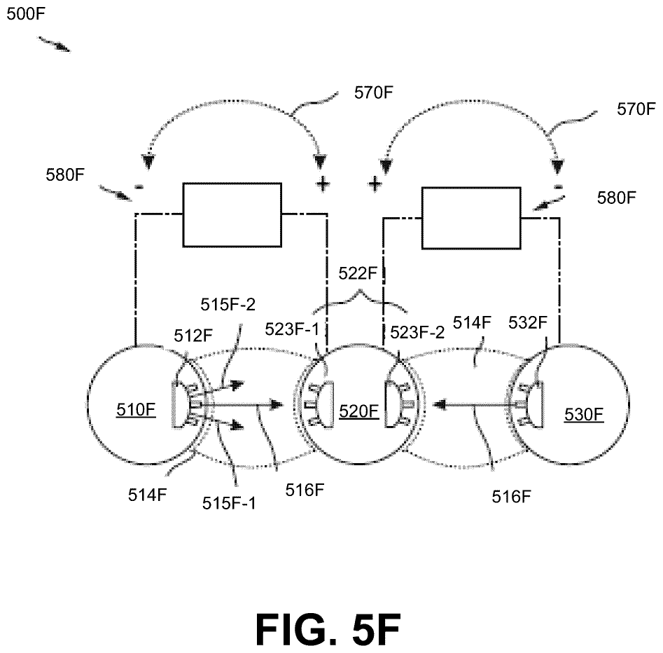

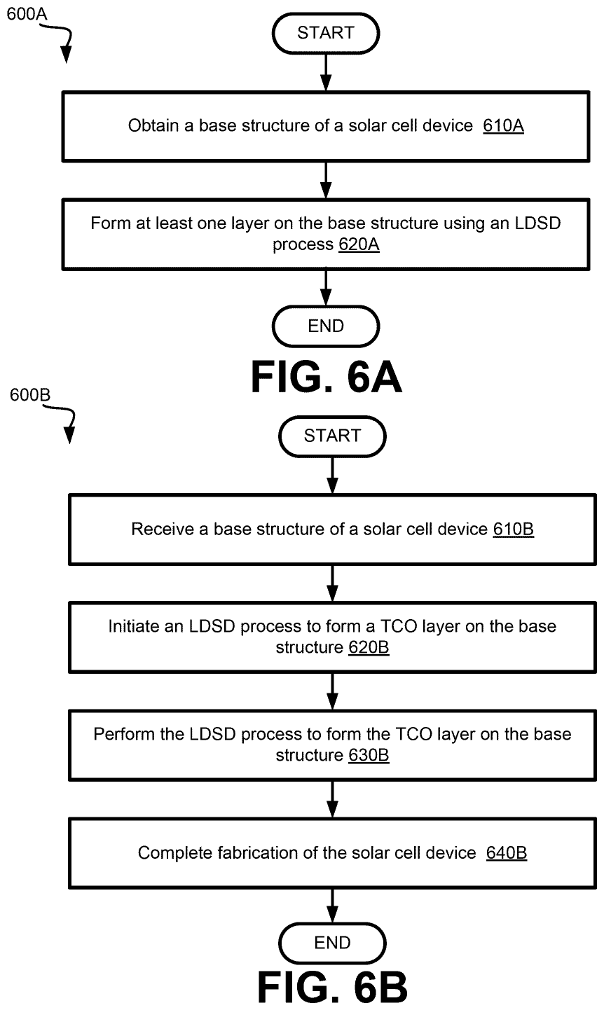

In some embodiments, an LDSD system is a rotatable facing target sputtering (RFTS) system to perform an RFTS process. In an RFTS system, instead of facing the substrate directly, flat/planar rotary targets face each other, which has the effect of a reduced bombardment of energetic particles on the substrate. More specifically, a front sputter magnet assembly can be arranged in a rotary target that faces toward an adjacent magnetron sputter cathode, instead of directly toward the substrate. Performing the RFTS process can include directing first sputter material from a first rotary target with a facing magnet yoke position towards a second rotary target and directing second sputter material from the second rotary target with a facing magnet yoke position towards the first rotary target. In contrast to other sputter deposition processes, RFTS processes can minimize sputtering damage, while allowing access to material choices not accessible by evaporation or providing faster deposition as compared to other deposition techniques, such as atomic layer deposition (ALD). Further details regarding LDSD systems and processes (e.g., RFTS systems and processes) will be described herein below with reference to FIGS. 5A-6B.

A TCO layer formed using an LDSD process can include any suitable material or combinations of materials in accordance with embodiments described herein. In some embodiments, the TCO layer includes IZO. In some embodiments the TCO layer includes ITO. The composition of the TCO layer can be chosen depending on target properties (e.g., optical properties) of the TCO layer for a particular application. For example, if the TCO layer includes IZO, then the TCO layer can include a first amount of indium oxide (In₂O₃) and a second amount of ZnO. In some embodiments, the TCO layer includes IZO including about 90% In₂O₃ and about 10% ZnO. As another example, if the TCO layer includes ITO, then the TCO layer can include a first amount of In₂O₃ and a second amount of a tin oxide (e.g., SnOₓ). In some embodiments, the TCO layer includes ITO including about 90% In₂O₃ and about 10% of the tin oxide. In some embodiments, the ITO layer includes AZO. In some embodiments, the ITO layer includes ICO.

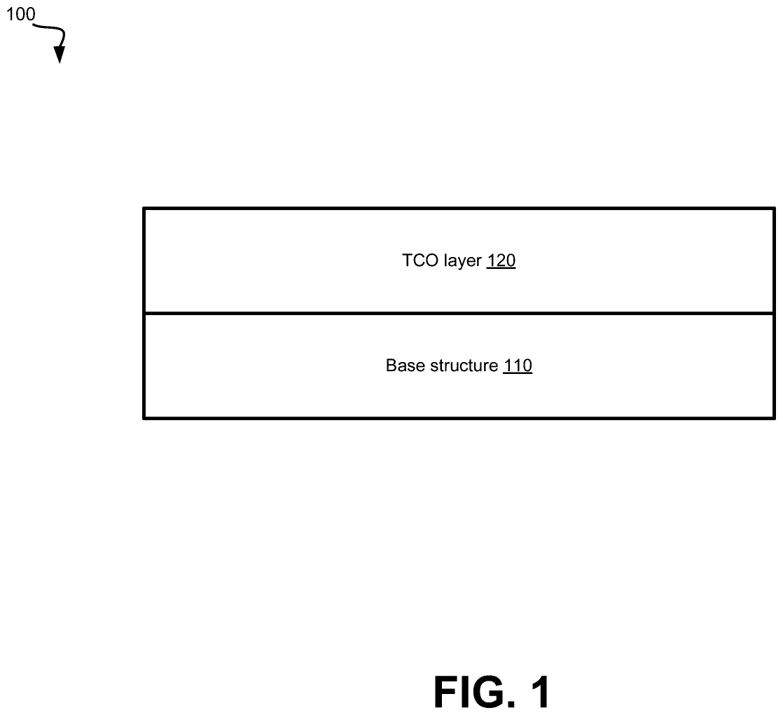

Fabricating the tandem solar cell device can further include completing fabrication of the tandem solar cell device. For example, if the base structure includes a stack of layers including an ETL of a solar cell (e.g., a perovskite solar cell), then completing fabrication of the tandem solar cell device can include forming a set of electrodes on the TCO layer (e.g., a set of Ag electrodes). As another example, if the base structure includes a stack of alternating semiconductor layers of a solar cell (e.g., an HJT solar cell), then completing fabrication of the tandem solar cell device can include forming a set of electrodes on the TCO layer (e.g., a set of Ag electrodes). As yet another example, if the base structure includes a first solar cell of the tandem solar cell device (e.g., an HJT solar cell) and the TCO layer is a recombination layer formed on the first solar cell, then completing fabrication of the tandem solar cell device can include forming a second solar cell of the tandem solar cell device (e.g., a perovskite solar cell) on the recombination layer. Then, a set of electrodes can be formed on the second solar cell (e.g., a set of Ag electrodes). Further details regarding fabricating tandem solar cell devices with to reduce active layer damage will now be described below with reference to FIGS. 1-11.

FIG. 1 is a block diagram of an example portion of electronic device (“device”) 100, in accordance with some embodiments. More specifically, device 100 includes a tandem solar cell device. In some embodiments, the tandem solar cell device is a perovskite/HJT tandem solar cell device.

As shown, device 100 can include base structure 110 and TCO layer 120 disposed on base structure 110. TCO layer 120 can be formed using a low damage sputter deposition (LDSD) process. TCO layer 120 can include any suitable TCO material. In some embodiments, TCO layer 120 includes IZO. In some embodiments, TCO layer 120 includes ICO. In some embodiments, TCO layer 120 includes ITO. In some embodiments, TCO layer 120 includes AZO. In some embodiments, TCO layer 120 includes a combination of ITO and AZO. The composition of TCO layer 120 can be chosen depending on target properties (e.g., optical properties) of the TCO layer for a particular application. For example, if TCO layer 120 includes IZO, then TCO layer 120 can include a first amount of In₂O₃ and a second amount of ZnO. In some embodiments, TCO layer 120 is an IZO layer including about 90% In₂O₃ and about 10% ZnO. As another example, if TCO layer 120 includes ITO, then TCO layer 120 can include a first amount of In₂O₃ and a second amount of a tin oxide (e.g., SnOₓ). In some embodiments, TCO layer 120 is an ITO layer including about 90% In₂O₃ and about 10% of the tin oxide.

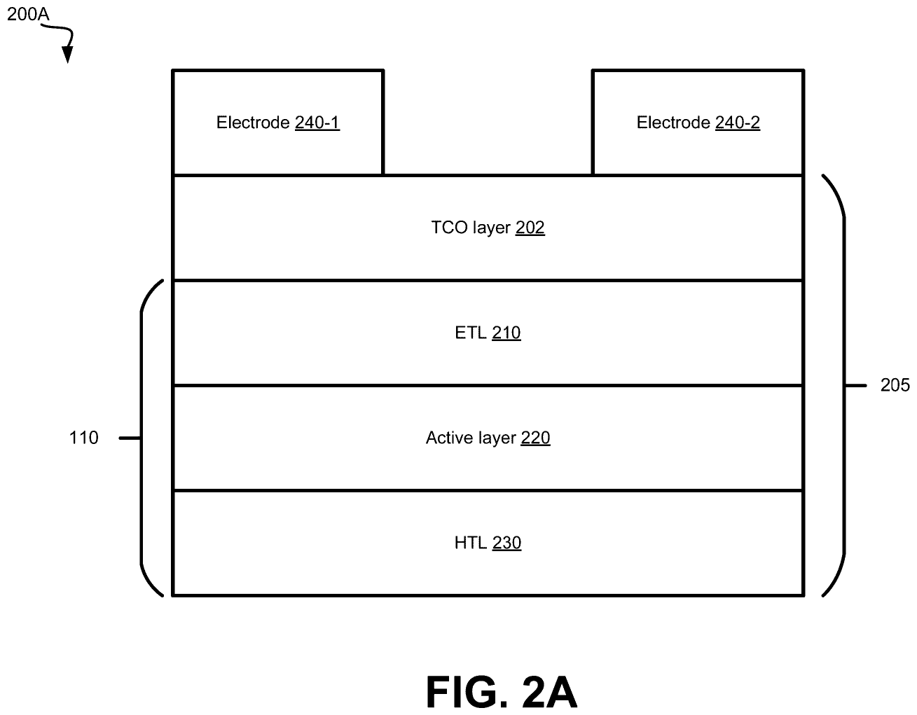

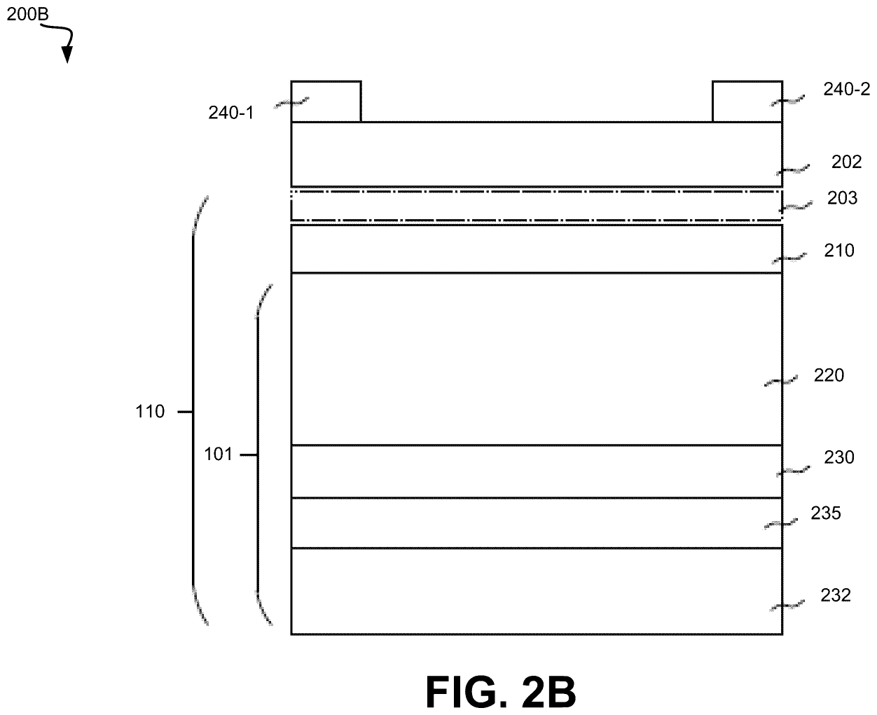

In some embodiments, base structure 110 includes a stack of layers including an ETL of a solar cell of device 100, with TCO layer 120 being disposed on the stack of layers (e.g., the ETL). Additionally, the ETL can be disposed on an active layer. In some embodiments, the active layer includes a perovskite layer and device 100 includes a perovskite solar cell. Additionally, the active layer disposed on an HTL. Additionally, a set of electrodes (not shown in FIG. 1) can be formed on TCO layer 120. Each electrode of the set of electrodes can include any suitable material. For example, each electrode of the set of electrodes can include silver (Ag). Further details regarding these embodiments will be described below with reference to FIGS. 2A-2B.

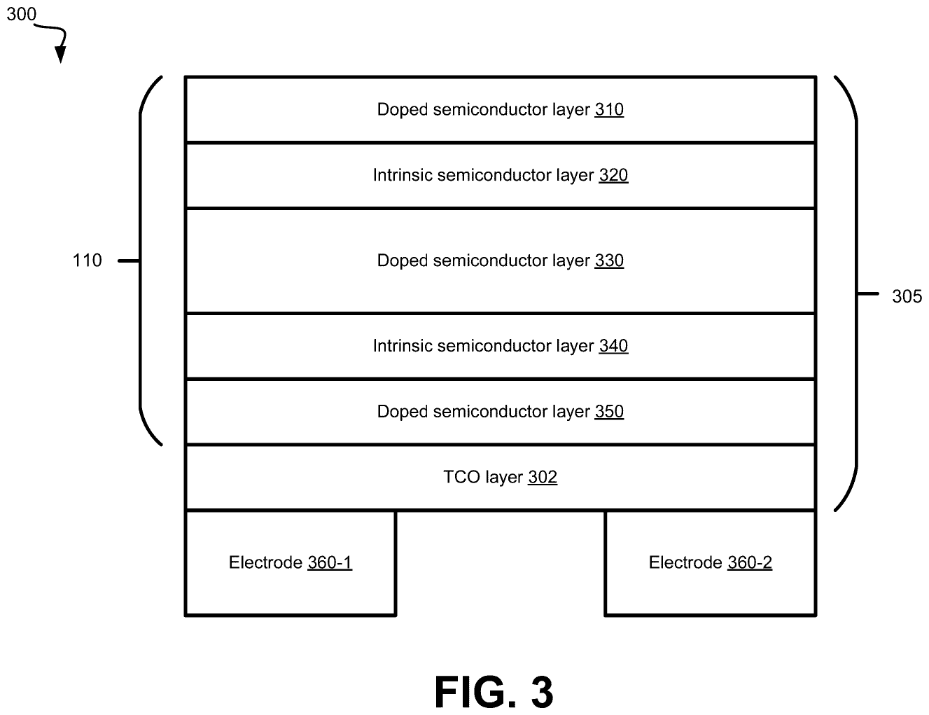

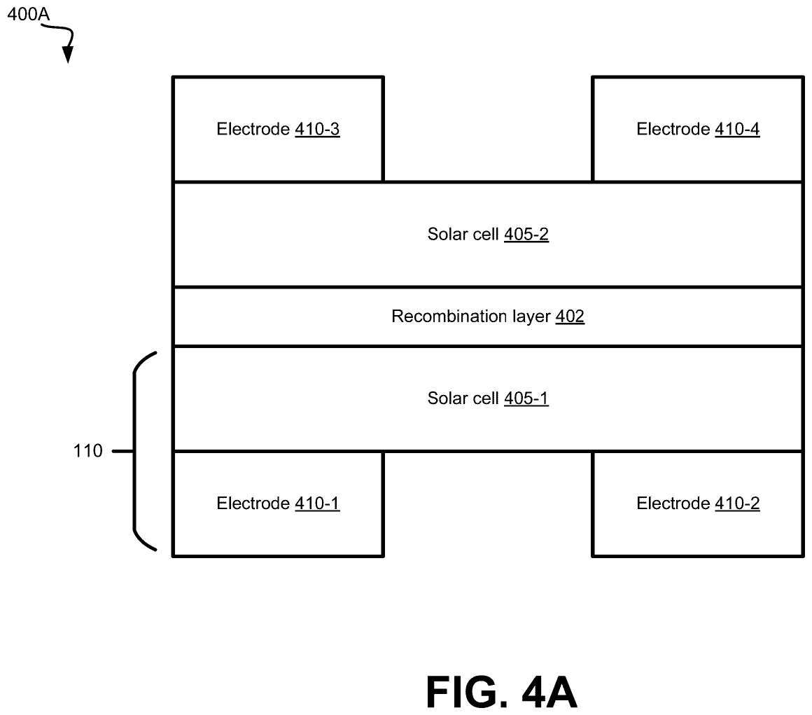

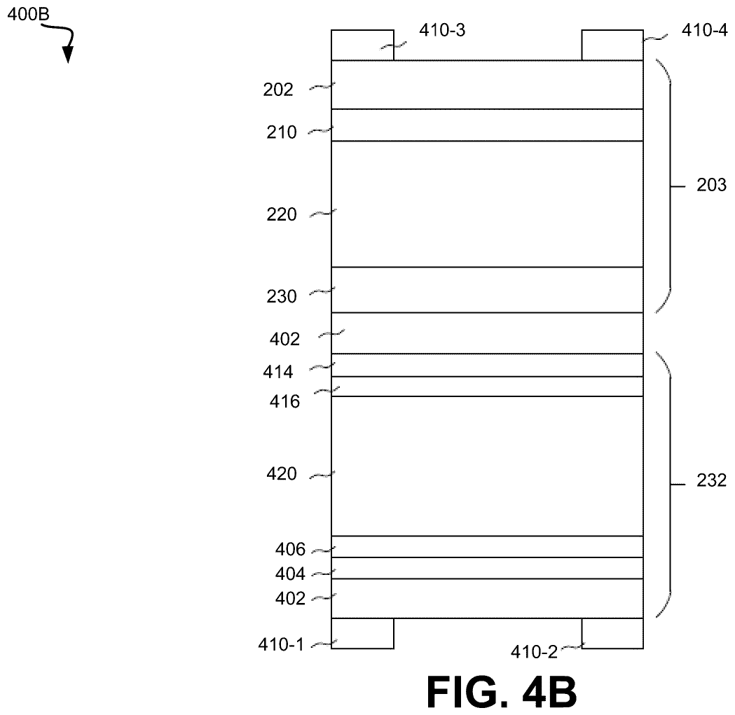

In some embodiments, base structure 110 includes a stack of alternating semiconductor layers of a solar cell of device 100, with TCO layer 120 being disposed on the stack of alternating semiconductor layers. Each semiconductor layer of the stack of alternating semiconductor layers may be formed from a different type of semiconductor material (e.g., doped semiconductor material or intrinsic semiconductor material). An HJT interface is defined at the boundary region where a respective pair of semiconductor layers of the stack of alternating semiconductor layers meet, which can form an electric field that facilitates the separation and collection of electron-hole pairs. Additionally, a set of electrodes (not shown in FIG. 1) can be formed on TCO layer 120. Each electrode of the set of electrodes can include any suitable material. For example, each electrode of the set of electrodes can include Ag. Further details regarding these embodiments will be described below with reference to FIGS. 3-4.

In some embodiments, base structure 110 includes a first solar cell of device 100. For example, base structure 110 can include the first solar cell and a first set of electrodes (e.g., set of Ag electrodes) disposed on the first solar cell. In some embodiments, the first solar cell is an HJT solar cell. In these embodiments, TCO layer 120 can correspond to a recombination layer disposed on base structure 110 (e.g., on the first semiconductor layer of the HJT solar cell). A second solar cell of the tandem solar cell device (e.g., a perovskite solar cell) can then be formed on TCO layer 120 (not shown in FIG. 1). For example, the second solar cell can include a TCO layer disposed on a stack of layers including an ETL (e.g., a perovskite solar cell), and a second set of electrodes (e.g., set of Ag electrodes) disposed on the TCO layer. Accordingly, TCO layer 120 can be disposed between the first solar cell and the second solar cell. Further details regarding these embodiments will be described below with reference to FIGS. 3-4.

TCO layer 120 can be formed on base structure 110 using an LDSD process as part of a process to fabricate device 100. Further details regarding fabricating device 100, including forming TCO layer 120 on base structure 110 using an LDSD process, will be described below with reference to FIGS. 5-6.

FIG. 2A is a block diagram of an example portion of a tandem solar cell device (“device”) 200A, in accordance with some embodiments. As shown, device 200A can include base structure 110 as described above with reference to FIG. 1 and TCO layer 202 disposed on base structure 110. In some embodiments, TCO layer 202 is TCO layer 120 of FIG. 1. More specifically, base structure 110 corresponds to a base structure of solar cell 205 of device 200A. For example, solar cell 205 includes TCO layer 120 disposed on ETL 210. ETL 210 can include a material selected to enable electron transport. Examples of materials that can be used to form ETL 210 include TiO₂, ZnO, SnO₂, etc. In some embodiments, ETL 210 functions as a barrier layer to prevent the diffusion of impurities, which can improve stability and longevity of solar cell 205. ETL 210 can be formed using any suitable process. For example, ETL 210 can be formed using an evaporation process.

As further shown, ETL 210 can be disposed on active layer 220. In some embodiments, solar cell 205 is a perovskite solar cell and active layer 220 includes a perovskite layer including a perovskite material. In some embodiments, device 200A is a perovskite/HJT tandem solar cell device. The perovskite material can have a set of properties (e.g., bandgap) that enables absorption of solar radiation and generation of a larger number of electron-hole pairs, which can be separated and collected to generate an electrical current. One example of a perovskite material that can be used to form the perovskite layer is CH₃NH₃PbI₃. Active layer 220 can be formed using any suitable process. For example, a perovskite layer can be formed using an evaporation process, a chemical vapor deposition process (CVD), a printing process, etc.

As further shown, active layer 220 can be disposed on HTL 230 that can extract and transport holes (i.e., positive charges). HTL 230 can be formed from a material that has high hole mobility to enable transport of holes. For example, HTL 230 can be formed from a nickel oxide (e.g., NiOₓ), a molybdenum oxide (MoOₓ), a vanadium oxide (VOₓ), a tungsten oxide (WOₓ), a copper oxide (CuOₓ or CuₓO), a copper gallium oxide (CuGaOₓ), a copper aluminum oxide (CuAlOₓ), a copper chromium oxide (e.g., CuCrOₓ), ZnO, an aluminum nickel oxide (Al_{y}Ni_{1-y}Oₓ), spiro-OMeTAD, PEDOT, etc. HTL 230 can be formed using any suitable process. For example, HTL 230 can be formed using an evaporation process.

As further shown, electrode 240-1 and electrode 240-2 can be disposed on TCO layer 202. Electrode 240-1 and electrode 240-2 can include any suitable material. For example, electrode 240-1 and electrode 240-2 can include Ag. Further details regarding device 200A are described above with reference to FIG. 1 and will be described in further detail below with reference to FIGS. 5-6B.

FIG. 2B is a block diagram of an example portion of a solar cell device (“device”) 200B, in accordance with some embodiments. As shown in FIG. 2B, device 200B may include a base structure 110. The base structure may include a substrate 232, for example, a glass substrate. A bottom electrode 235 can be deposited over the substrate 232. An HTL 230 layer can be deposited over the bottom electrode 235. Further, an active layer 220 can be provided over the HTL 230. According to some embodiments, the active layer 220 can be a perovskite layer. The ETL 210 can be deposited over the active layer. As indicated by the dashed lines in FIG. 2B, a buffer layer 203, which may be provided for protecting the active layer from a subsequent TCO deposition, can be optional, particularly in light of an LDSD process utilized for depositing an TCO layer 202 onto the base structure 110. As described above, electrode 240-1 and electrode 240-2 can be provided on the TCO layer 202. According to some embodiments, which can be combined with other embodiments described herein, the HTL, the active layer, the ETL and the TCO layer can be provided by or can include respective materials as described with respect to other embodiments of the present disclosure.

According to some embodiments, the base structure 110 may also be provided by a layer stack as indicated by reference 101 in FIG. 2B. Accordingly, the uppermost layer of the base structure 110 can be the active layer 220, for example, a perovskite layer or another sensitive active layer. An ETL 210 including or consisting of, for example, SnOₓ or ZnOₓ, can be deposited with an LDSD process, such as an RFTS process. An ETL 210 including, for example, TiOₓ, ZnₓTi_{y}O_{z}, and/or BaₓSn_{y}O_{z}, can be deposited with an LDSD process, such an RFTS process. As a further optional implementation, a TCO layer 202 can be deposited with an LDSD process, such as an RFTS process. The TCO layer 202 may include one or more of IZO, ITO, AZO, SnO, ZnO.

In some embodiments, an RFTS process uses direct current (DC) sputtering with a DC power supply. In some embodiments, an RFTS process uses alternating current (AC) sputtering with an AC power supply. In some embodiments, an RFTS process uses bipolar pulsed sputtering.

According to some embodiments, which can be combined with other embodiments described herein, the layer stack shown in FIG. 2B (e.g. without the substrate 232) may also be deposited in an inverse direction, i.e. top-down. In such a case, the HTL 230 is deposited on the active layer 220. The HTL may include or consists of one or more materials selected from the group consisting of: NiOₓ, MoOₓ, VOₓ, WOₓ, CuOₓ & CuₓO, CuGaOₓ, CuAlOₓ, CuCrOₓ, ZnO, and Al_{y}Ni_{1-y}Oₓ. Accordingly, the HTL can be deposited with an LDSD process.

As explained in more detail below, an RFTS process can utilize one or more anodes or chamber components acting as an anode. Materials deposited during the LDSD process, which have an insufficient electrical conductivity, may jeopardize over time the functionality of the anode by deposition material covering the anode. Accordingly, such materials may not be utilized with an RTFS processing using DC sputtering for large volume manufacturing conditions, for which maintenance cycles are of interest. Accordingly, a plurality of materials, which may be deposited during manufacturing of solar cell device with an LDSD process, according to embodiments of the present disclosure, can be deposited with an RFTS process using AC sputtering.

FIG. 3 is a block diagram of an example portion of a tandem solar cell device (“device”) 300, in accordance with some embodiments. As shown, device 300 can include base structure 110 as described above with reference to FIG. 1 and TCO layer 302 disposed on base structure 110. In some embodiments, TCO layer 302 is TCO layer 120 of FIG. 1. More specifically, device 300 base structure 110 corresponds to a base structure of solar cell 305. In this example, solar cell 305 is an HJT solar cell. In some embodiments, device 300 is a perovskite/HJT tandem solar cell device. For example, as shown, solar cell 305 includes stack of alternating semiconductor layers (“stack”) 305. Each semiconductor layer of stack 305 is formed from a different type of semiconductor material. For example, as shown, stack 305 includes doped semiconductor layer 310 including a doped semiconductor material disposed on intrinsic semiconductor layer 320 including an intrinsic semiconductor material, intrinsic semiconductor layer 320 disposed on doped semiconductor layer 330 including a doped semiconductor material, doped semiconductor layer 330 disposed on intrinsic semiconductor layer 340 including an intrinsic semiconductor material, and intrinsic semiconductor layer 340 disposed on doped semiconductor layer 350 including a doped semiconductor material. As further shown, doped semiconductor layer 350 is disposed on TCO layer 302. As further shown, electrode 360-1 and electrode 360-2 can be disposed on TCO layer 302. Electrode 360-1 and electrode 360-2 can include any suitable material. For example, electrode 360-1 and electrode 360-2 can include Ag.

In some embodiments, the first semiconductor layer and the third semiconductor layer each include an n-type semiconductor material and the fifth layer includes a p-type semiconductor material. In some embodiments, the first semiconductor layer and the third semiconductor layer each include a p-type semiconductor material and the fifth layer includes an n-type semiconductor material. In some embodiments, each semiconductor layer 310-350 includes Si. For example, doped semiconductor layer 310 can be a doped a-Si layer, intrinsic semiconductor layer 320 can be an intrinsic i-Si layer, doped semiconductor layer 330 can be a doped c-Si layer (e.g., monocrystalline Si or polycrystalline Si), intrinsic semiconductor layer 340 can be an i-Si layer, and doped semiconductor layer 330 can be an a-Si layer. In some embodiments, doped semiconductor layer 310 and doped semiconductor layer 330 are each n-type layers (e.g., n-a-Si and n-c-Si) and doped semiconductor layer 350 is a p-type layer (i.e., p-a-Si). In some embodiments, doped semiconductor layer 310 and doped semiconductor layer 330 are each p-type layers (e.g., p-a-Si and p-c-Si) and doped semiconductor layer 350 is an n-type layer (e.g., n-a-Si). Further details regarding device 300 are described above with reference to FIG. 1 and will be described in further detail below with reference to FIGS. 5-6B.

FIG. 4A is a block diagram of an example tandem solar cell device (“device”) 400A, in accordance with some embodiments. As shown, device 400A can include base structure 110 as described above with reference to FIG. 1 and recombination layer 402 disposed on base structure 110. In some embodiments, recombination layer 402 is TCO layer 120 of FIG. 1. In this example, base structure 110 corresponds to a base structure of device 400A including solar cell 405-1, and electrode 410-1 and electrode 410-2 disposed on solar cell 405-1. Electrode 410-1 and electrode 410-2 can include any suitable material. For example, electrode 410-1 and electrode 410-2 can include Ag.

More specifically, device 400A includes solar cell 405-1 and solar cell 405-2, where recombination layer 402 is disposed between solar cell 405-1 and solar cell 405-2. For example, recombination layer 402 can be a TCO layer. As further shown, electrode 410-3 and electrode 410-4 can be disposed on solar cell 405-2. Electrode 410-3 and electrode 410-4 can include any suitable material. For example, electrode 410-3 and electrode 410-4 can include Ag.

In some embodiments, solar cell 405-1 includes a stack of alternating semiconductor layers disposed on a TCO layer, where electrode 410-1 and electrode 410-2 are disposed on the TCO layer of solar cell 405-1. In some embodiments, solar cell 405-1 is solar cell 305 of FIG. 3 and electrodes 420-1 and 420-2 are electrodes 360-1 and 360-2, respectively, of FIG. 3. For example, solar cell 405-1 can be an HJT solar cell. In some embodiments, the TCO layer of solar cell 405-1 is formed using an LDSD process similar to TCO layer 120. Further details regarding solar cell 405-1 are described above with reference to FIGS. 1 and 3 and will be described below with reference to FIGS. 5-6.

In some embodiments, solar cell 405-2 includes a TCO layer disposed on a stack of layers including an ETL, where electrode 410-3 and electrode 410-4 are disposed on the TCO layer of solar cell 405-2. In some embodiments, solar cell 405-2 is solar cell 205 of FIG. 2 and electrodes 420-3 and 420-4 are electrodes 240-1 and 240-2, respectively, of FIG. 2. For example, solar cell 405-2 can be a perovskite solar cell. In some embodiments, device 400A is a perovskite/HJT tandem solar cell device. In some embodiments, the TCO layer of solar cell 405-2 is formed using an LDSD process similar to TCO layer 120 (e.g., recombination layer 402). Further details regarding solar cell 405-2 are described above with reference to FIGS. 1 and 3 and will now be described below with reference to FIGS. 5-6.

Similar to FIG. 4A, FIG. 4B shows a tandem solar cell device (“device”) 400B having a solar cell 405-1 and a solar cell 405-2. The two solar cells have a recombination layer 402 between the solar cell 405-1 and the solar cell 405-2. The various embodiments and implementations described with respect to device 400A of FIG. 4A may also be implemented for device 400B of FIG. 4B.

Device 400B may include an electrode 410-1 and an electrode 410-2. A TCO layer 402 can be provided. For example, an n-type amorphous silicon layer 404 can be provided and an intrinsic amorphous silicon layer 406 can be provided over the n-type amorphous silicon layer 404. A nano-crystalline silicon (nc-Si) or micro-crystalline silicon (pc-Si) layer 420 can serve as an active layer of the solar cell 405-1. An intrinsic amorphous silicon layer 416 can be provided over the active layer 420 and an n-type amorphous silicon layer 414 can be provided over the intrinsic amorphous silicon layer 416. The recombination layer 402 can be provided by a TCO layer according to embodiments described herein. Further, according to some embodiments, which can be combined with other embodiments described herein, the solar cell 405-2 can be provided according to other embodiments described herein, particularly with respect to FIG. 2B, and more particularly including a perovskite layer as the active layer 220.

As described with respect to FIG. 2B, a plurality of layers of the solar cell device exemplarily shown in FIG. 4B can be provided with an LDSD process utilizing rotatable facing targets sputtering with a DC process or an AC process, and particularly with an AC process. For example, the recombination layer 402 may formed using an LDSD process. Further, as previously described with respect to FIG. 2B, the HTL 230 and the ETL 210 may be provided with an LDSD process as described herein. In light of the reduced energy impact and UV impact of the LDSD process, a buffer layer can be avoided between the ETL 210 and the TCO layer 202.

According to some embodiments, which can be combined with other embodiments described herein, the solar cell 405-1 may be a thin-film solar cell device. A thin-film solar cell device may be manufactured by depositing the active layer 420 with CVD or a PVD process, for example a sputter deposition process. Accordingly, a micro-crystalline thin-film solar cell (e.g. pc-Si) can be provided as the solar cell 405-1. In light of the sensitivity of a pc-Si layer, an LDSD process for the recombination layer can be beneficially utilized.

FIGS. 5A and 5B are diagrams of example systems 500A and 500B, respectively, for fabricating tandem solar cell devices to reduce active layer damage, in accordance with some embodiments. Systems 500A and 500B can include a processing chamber communicably coupled to a controller. Systems 500A and 500B can be used to form a TCO layer on a base structure of a tandem solar cell device using an LDSD process during fabrication of the tandem solar cell device. In some embodiments, systems 500A and 500B can perform an LDSD process to form material at least one material on substrate 502A. In some embodiments, substrate 502A is a base structure of a tandem solar cell device.

For example, systems 500A and 500B can each include at least one of first rotary target 510A or second rotary target 520A, each mounted to a respective target support. In embodiments, systems 500A and 500B includes both rotary targets 510A and 520A. Aperture plate 540A can be provided. Aperture plate 540A can include at least one aperture 542A and shielding portion 544A. Shielding portion 544A can be provided at least at center line 534A perpendicular to the surface of substrate 502. Center line 534A corresponds to a center of the plasma region between first rotary target 510A and second rotary target 520A. Shielding portion 544A blocks material particles from first rotary target 510A and/or second rotary target 520A moving towards the substrate. As shown in FIG. 5A, aperture plate 540A of system 500A can have a symmetric arrangement relative to shielding portion 544A. As shown in FIG. 5B, aperture plate 540A of system 500B has an asymmetric arrangement relative to shielding portion 544A.

Systems 500A and 500B can include first magnet assembly 512A connectable to the first target support. For example, first magnet assembly 512A can be positioned within first rotary target 510A. Systems 500A and 500B can further include second magnet assembly 522A connectable to the second target support. For example, second magnet assembly 522A can be positioned within second rotary target 520A. In this illustrative example, rotary targets 510A and 520A are neighboring targets, such that there are no further rotary targets positioned between rotary targets 510A and 520A.

Generally, a target support for a rotary target (e.g. first rotary target 510A and/or second rotary target 520A) can include at least one end block. An end block may include a target mounting flange configured to support a rotary target while allowing rotation relative to the end block. The end block may include at least one utility shaft configured to support at least one magnet assembly (e.g., first magnet assembly 512A and/or second magnet assembly 522A). The end block may include a fitting for delivery of a cooling fluid to the rotary target.

Plasma associated with the sputter deposition may be trapped between rotary targets 510A and 520A. First plasma confinement 514A of first magnet assembly 512A and second plasma confinement 524A of second magnet assembly 522A may overlap at least partially. Plasma confinements 514A and 524A can each correspond to a respective plasma confinement region. A plasma confinement region refers to a region where the amount of plasma is increased relative to the environment, particularly due to the effect of a magnetic field of a magnet assembly located in a rotary target. For example, providing a plasma confinement in a specific direction is refers to providing the plasma confinement such that a main direction of the plasma confinement extends in the specific direction.

In embodiments in which a magnet assembly (e.g., first magnet assembly 512A and/or second magnet assembly 522A) includes a permanent magnet, providing a plasma confinement in a specific direction (e.g., first plasma confinement 514A and/or second plasma confinement 524A) can include providing the magnet assembly at a position such that the magnet assembly faces the specific direction. For example, a symmetry axis of the magnet assembly faces the specific direction. For example, providing a plasma confinement in a direction facing a rotary target (e.g., rotary target 510A or rotary target 520A), such as a neighboring rotary target, may be understood as the magnet assembly facing the rotary target. In some embodiments, a plasma confinement is provided in a plasma racetrack, particularly a closed plasma racetrack. The plasma confinement associated with one magnet assembly provides a closed loop. The closed loop may for example be provided at one target, i.e. the target in which the magnet assembly is provided.

A magnet assembly positioned within a rotary target (e.g., first magnet assembly 512A positioned with first rotary target 510A or second magnet assembly 522A positioned within second rotary target 520A) may enable magnetron sputtering. As used herein, “magnetron sputtering” refers to sputtering performed using a magnetron, i.e. a rotary target having a magnet assembly positioned within. A magnet assembly refers to a unit capable of generating a magnetic field. A magnet assembly may include one or more permanent magnets. The permanent magnets may be arranged within a rotary target such that free electrons are trapped within the generated magnetic field, e.g. in a closed loop or a racetrack. The magnet assembly can be provided within a backing tube of the rotary target or within the target material tube.

In rotary targets 510A and 520A, the removal of material from the target during magnetron sputtering has an improved uniformity, when compared to magnetron sputtering from planar targets. The uniformity in the case of rotary targets 510A and 520A is particularly caused by the movement of the target surface relative to the magnetic field due to the rotation of rotary targets 510A and 520A. The amount of material collected on a target surface may be reduced or even eliminated. Stability, particularly long-term stability of the deposition process may be increased. Use of the facing target sputtering concept for mass production may be enabled, in light of the reduced material collected and the stability of the process.

In some embodiments, first magnet assembly 512A includes at least three magnetic poles facing plasma confinement 514A provided by first magnet assembly 512A, and second magnet assembly 522A includes at least three magnetic poles facing plasma confinement 524A provided by second magnet assembly 522A. Rotary targets 510A and 520A can be positioned in deposition chamber 552A. For example, deposition chamber 552A can be a vacuum chamber. A first additional chamber and a second additional chamber may be provided adjacent to the deposition chamber (not shown).

In some embodiments, the LDSD process is a dynamic deposition process. For example, substrate 502 can move past rotary targets 510A and 520A while material is deposited on substrate 502A, as indicated by arrow 505A. Accordingly, an in-line deposition process can be provided.

In some embodiments, the LDSD process is a static deposition process. The static deposition process can include depositing material in a batch process. A substrate is moved into the deposition chamber. Substrate 502A can be moved back and forth past aperture plate 540A as indicated by arrow 507A. Deposition chamber 552A may be separated from further chambers or other regions by a valve. After deposition in deposition chamber 552A, substrate 502A can be moved out of deposition chamber 552A and another substrate can be moved into deposition chamber 552A.

In some embodiments, process gases include at least one of a noble gas or a reactive gas. For example, a noble gas can be argon, krypton, xenon, or combinations thereof. For example, a reactive gas can be oxygen, nitrogen, hydrogen, ammonia (NH₃), nitrous oxide (N₂O), ozone (O₃), carbon oxide (CO₂), an activated gas, or combinations thereof.

Rotary targets 510A and 520A may be a cathode or a portion of a cathode. In some embodiments, systems 500A and 500B is configured for DC sputtering. In embodiments, systems 500A and 500B is configured for pulsed DC sputtering. Thus, rotary targets 510A and 520A can be cathodes electrically connected to a DC power supply. For example, components like a housing of the deposition chamber or at least one shield within the deposition chamber can be provided on mass potential. Such components may serve as an anode. Optionally, systems 500A and 500B may further include anodes. In embodiments, at least one first rotary target 510A or second rotary target 520A is electrically connected to a respective individual power supply. For example, first rotary target 510A may be connected to a first DC power supply and second rotary target 520A may be connected to a second DC power supply.

In embodiments where non-reactive sputtering is performed, the material to be deposited on substrate 502 may be sputtered from any first rotary target 510A or second rotary target 520A. This is particularly to be understood such that particles ejected from a surface of first rotary target 510A or second rotary target 520A form the deposited material. In embodiments in which reactive sputtering is performed, particles of a first material may be ejected from a surface of any of first rotary target 510A or second rotary target 520A. The first material can be understood to be a component of the deposited material. A gas surrounding first rotary target 510A and second rotary target 520A may include the second material.

FIGS. 5C and 5C are diagrams of example systems 500C and 500D, respectively, for fabricating tandem solar cell devices to reduce active layer damage, in accordance with some embodiments. Systems 500C and 500D can include a processing chamber communicably coupled to a controller. Systems 500C and 500D can be used to form a TCO layer on a base structure of a tandem solar cell device using an LDSD process during fabrication of the tandem solar cell device. In some embodiments, systems 500C and 500D can perform an LDSD sputter deposition process to form material at least one material on substrate 502C. In some embodiments, substrate 502C is a base structure of a tandem solar cell device. Substrate 502C may be provided on substrate holder 504. In some embodiments, transportation of substrate 502C can be provided by a magnetic levitation system.

Systems 500C and 500D can include a first target support for first rotary target 510C and a second target support for second rotary target 520C. Rotary targets 510C and 520C can each be mounted to the respective target support. Systems 500C and 500D can include first magnet assembly 512C connectable to the first target support. For example, when first magnet assembly 512C is connected and first rotary target 510C is mounted to the first target support, first magnet assembly 512C can be positioned within first rotary target 510C. The system further includes a second magnet assembly 522C connectable to the second target support. For example, when second magnet assembly 522C is connected and second rotary target 520C is mounted to the second target support, second magnet assembly 522C is positioned within second rotary target 520C. For example, rotary targets 510C and 520C can be neighboring targets and there are no further rotary targets positioned in a region between rotary targets 510C and 520C. Generally, a target support for a rotary target may include at least one end block. An end block may include a target mounting flange configured to support a rotary target while allowing rotation relative to the end block. The end block may include at least one utility shaft configured to support at least one magnet assembly. The end block may include a fitting for delivery of a cooling fluid to the rotary target.

Plasma associated with the sputter deposition may be trapped between rotary targets 510C and 520C. A plasma confinement of first magnet assembly 512C and plasma confinement of second magnet assembly 522C may overlap at least partially. A plasma confinement can be understood as a plasma confinement region. A plasma confinement region refers to a region where the amount of plasma is increased relative to the environment, due at least in part to a magnetic field of a magnet assembly located in a rotary target. Providing a plasma confinement in a specific direction can be understood as providing the plasma confinement such that a main direction of the plasma confinement extends in the specific direction. In some embodiments where a magnet assembly includes a permanent magnet, providing a plasma confinement in a specific direction can include providing the magnet assembly at a position such that the magnet assembly faces the specific direction. For example, a symmetry axis of the magnet assembly faces the specific direction. For example, a magnet assembly positioned to provide plasma confinement towards a rotary target (e.g., an adjacent rotary target) can be understood as facing that target. In some embodiments, a plasma confinement is provided in a plasma racetrack, particularly a closed plasma racetrack. The plasma confinement associated with one magnet assembly provides a closed loop. The closed loop may for example be provided at one target, i.e. the target in which the magnet assembly is provided.

Generally, a magnet assembly positioned within a rotary target may enable magnetron sputtering. As mentioned above with reference to FIGS. 5A-5B, “magnetron sputtering” refers to sputtering performed using a magnetron, i.e. a rotary target having a magnet assembly positioned within. A magnet assembly is particularly to be understood as a unit capable of generating a magnetic field. A magnet assembly may include one or more permanent magnets. The permanent magnets may be arranged within a rotary target such that free electrons are trapped within the generated magnetic field, e.g. in a closed loop or a racetrack. The magnet assembly can be provided within a backing tube of the rotary target or within the target material tube. Rotary targets described herein may be a cathode or a portion of a cathode. Systems 500C and/or 500D may be configured for DC sputtering. In embodiments, systems 500C and/or 500D may be configured for pulsed DC sputtering.

A rotary target can be a rotatable sputtering target, such as a cylindrical sputtering target. For example, the rotary target may be a rotatable cathode including a material to be deposited. The rotary target may be connected to a shaft configured to rotate in at least one operational state of the system. The rotary target may be connected to the shaft directly or indirectly via a connecting element. According to some embodiments, the rotary targets in a deposition chamber may be exchangeable. Replacement of the rotary targets after the material to be sputtered has been consumed can be made possible. In rotary targets, the removal of material from the target during magnetron sputtering can achieve improved uniformity, when compared to magnetron sputtering from planar targets. The uniformity in the case of rotary targets can be caused by the movement of the target surface relative to the magnetic field due to the rotation of the targets. The amount of material collected on a target surface may be reduced or even eliminated. Arcing may be reduced or even eliminated. Material flaking may be reduced or eliminated. Stability, particularly long term stability of the deposition process may be increased. Use of the facing target sputtering concept for mass production may be enabled. Collection efficiency may be increased, due at least in part to the effect that an increased amount of material deposited on a target is sputtered again. Collection efficiency is particularly to be understood as the amount of a sputtered material captured by a substrate relative to the total amount of material emitted by a sputtering target. Material utilization may be increased. Material waste and costs may be reduced.

In some embodiments, magnet assemblies 512C and 522C each include at least three magnetic poles facing plasma confinements 514C provided by magnet assemblies 512C and 522C. As shown in FIGS. 5C-5D, magnet assemblies 512C and 522C each include three magnetic poles facing plasma confinements 514C.

Rotary targets 510C and 520C may be positioned in deposition chamber 552C. For example, deposition chamber 552C can be a vacuum chamber. A first additional chamber and a second additional chamber may be provided adjacent to the deposition chamber (not shown). In some embodiments, depositing a TCO layer on substrate 502C can be provided with a dynamic deposition process. For example, substrate 502C can move past rotary targets 510C and 520C while the TCO layer is being deposited. Deposition chamber 552C or regions of a vacuum processing system may be separated from further chambers or other regions by a valve. In some embodiments, process gases can include at least one of a noble gas or a reactive gas. For example, a noble gas can be argon, krypton, xenon, or combinations thereof. For example, a reactive gas can be oxygen, nitrogen, hydrogen, NH₃, O₃, an activated gas, or combinations thereof.

Each of rotary targets 510C and 520C may be a cathode electrically connected to a DC power supply. For example, components like a housing of deposition chamber 552C or at least one shield within deposition chamber 552C can be provided on mass potential and can serve as an anode. Optionally, systems 500C and/or 500D may further include anodes. In some embodiments, at least one or more of rotary targets 510C and 520C may be electrically connected to a respective individual power supply. For example, each of rotary targets 510C and 520C may be connected to a respective individual power supply (e.g., DC power supply).

In some embodiments where non-reactive sputtering is performed, the material to be deposited on substrate 502C may be sputtered from any of first rotary target 510C and/or second rotary target 520C. This is particularly to be understood to mean that particles ejected from a surface of first rotary target 510C and/or second rotary target 520C can form the material deposited on substrate 502C. In some embodiments where reactive sputtering is performed, particles of a first material may be ejected from a surface of any of first rotary target 510C or second rotary target 520C. The particles of the first material may combine with a second material to form the material to be deposited on substrate 502. The first material can be understood to be a component of the deposited material. A gas surrounding rotary targets 510C and 520C may include the second material. In some embodiments, the plasma associated with the sputtering and the substrate are moved relative to each other during the deposition of a material on substrate 502C. For example, substrate 502C may oscillate during the deposition, particularly back and forth between two positions.

Systems 500C and 500D can further include adjustable aperture 515C provided in a shield or between at least two shields, particularly as a gap between at least two shields. For example, aperture 515C may be provided between first shield 506C and second shield 516C. Shields provided in deposition chamber 552C may protect a back part of deposition chamber 552C. For example, assuming that rotary target 510C is mounted to the first target support, first shield 506C can be provided between first rotary target 510C and a deposition area where substrate 502C is to be located during a deposition. Analogously, second shield 516C may be provided between second rotary target 520C and the deposition area. In some embodiments, aperture 515C, particularly shields 506C and 516C providing aperture 515C, are electrically insulated. More particularly, shields 506C and 516C may have a defined electrical potential. Shields 506C and 516C may be cooled to a temperature that ranges between about 20° C. to about 85° C. Shields 506C and 516C may include flat surfaces. A surface of at least one of shields 506C and 516C may be roughened, particularly to avoid flaking.

An aperture size is particularly to be understood as a size of a gap between shields 506C and 516C, more particularly as the distance between shields 506C and 516C. A size of the aperture 515C may be adjustable by changing a distance between shields 506C and 516C. At one of first shield 506C or second shield 516C may be movable, particularly in a direction parallel to a substrate plane of the substrate 502C. For example, a size of the aperture 515C can be adjusted by moving at least one of the shields.

In some embodiments, first shield 506C includes first shield magnet assembly 508C. Second shield 516C may include second shield magnet assembly 518C. Second shield magnet assembly 518 may face first shield magnet assembly 516C. Each of the first shield magnet assembly's magnetic poles facing the second shield magnet assembly may have an opposite polarity to a respectively nearest magnetic pole of the second shield magnet assembly. The magnetic field in aperture 515C between shields 506C and 516C may be the field of a magnetic lens. In the magnetic field, charged particles may be deflected. A normal component with respect to a substrate surface of a momentum of charged particles may be reduced. The normal component of the momentum is responsible for the possible damage, particularly the possible depth of damage, caused by the charged particles to the substrate or the layer positioned on the substrate. Shields including shield magnet assemblies can mitigate damage to the substrate, particularly damage to sensitive coatings provided on the substrate.

Systems 500C and 500D can include a controller configured to control the system such that a method of depositing at least one material on a substrate, as described herein, is performed. For example, in embodiments systems 500C and/or 500D may perform an LDSD sputter deposition process to form a TCO layer on a solar cell. The method may be particularly suitable for a batch-type dynamic deposition system.

For example, a method can include a first deposition. An example of a configuration during the first deposition is shown in FIG. 5C. The first deposition can include sputtering from the first and the second rotary target through adjustable aperture 515C. First magnet assembly 512C provides plasma confinement 514C in a first direction facing second rotary target 520C, particularly during deposition of the material. Second magnet assembly 522C provides a plasma confinement 514C in a second direction facing the first rotary target 510C, particularly during deposition of the material. In other words, during the first deposition, the magnet assemblies may be in a facing target sputtering configuration.

In some embodiments, aperture 515C is smaller than a first size. For example, the first size can be 40 mm, 70 mm, 100 mm, or 130 mm. During the first deposition, aperture 515C may have a size of for example 50 mm. Generally, aperture 515C can have a size of for example 30 mm, 50 mm, or 70 mm during the first deposition. Aperture 515C may have a size larger than, for example, 5 mm, 15 mm, or 20 mm during the first deposition. The size of aperture 515C may be constant or it may change (e.g., increase) during the first deposition.

The feature that aperture 515C has a size smaller than the first size during the first deposition has the advantage that a spatial variation of the deposition rate on different parts of substrate 502C can be reduced (e.g., to prevent material from being simultaneously deposited on different parts of the substrate with highly differing deposition rates). For example, when the plasma confinement directions are facing each other directly, a substrate region facing a central region between rotary targets 510C and 520C could otherwise be exposed to a much higher deposition rate than other parts of substrate 502C. Aperture 515C having a size smaller than a first size during the first deposition can be beneficial for depositing material with an even thickness.

The feature that plasma confinements are provided in a first direction facing second rotary target 520C and in a second direction facing first rotary target 510C has the advantage that a soft deposition can be achieved. For example, bombardment of substrate 502C with high energy particles may be reduced. Damage to substrate 502C, particularly to a coating on the substrate, may be mitigated. This is particularly advantageous regarding deposition on sensitive substrates or layers, more particularly deposition on substrates having a sensitive coating. The first deposition can be understood as a protective deposition or a seed deposition.

The first direction and the second direction deviate from being parallel to a substrate plane of substrate 502C by an angle of less than a first value. The “substrate plane” refers to a plane of substrate 502C whereupon the material is deposited. The first value can range between about 100 to about 40°. As shown in FIG. 5A, the first and the second direction may be parallel to the substrate plane. In other words, an angle of deviation from an orientation parallel to the substrate plane may be 0°. In embodiments, the first direction and the second direction deviate from being parallel to the substrate plane by an angle of less than about 40° towards substrate 502C and less than 10° away from substrate 502C.

An advantageous configuration may be achieved, wherein bombardment of the substrate with energetic particles is minimized, while at least a satisfactory amount of material is deposited on substrate 502C. If any of the first and the second direction highly deviates from being parallel to the substrate plane in a direction towards substrate 502C, a disadvantageous bombardment of substrate 502C with energetic particles could ensue. If any of the first direction and the second direction highly deviates from being parallel to the substrate plane in a direction away from substrate 502C, an unsatisfactorily low deposition rate on substrate 502C could ensue. Additionally or alternatively, a waste of target material could arise.

The first direction may correspond to a first angle, particularly a first polar angle of a polar coordinate system. The reference point, particularly the pole, of the polar coordinate system, may be positioned on a rotation axis of the rotary target. The reference direction of the polar coordinate system may be perpendicular to the rotation axis of the rotary target. The deviation of the first direction from being parallel to a substrate plane may refer to a polar coordinate system of first rotary target 510C. The deviation of the second direction from being parallel to a substrate plane may refer to a polar coordinate system of second rotary target 520C.

In some embodiments, magnets included in each of the system's magnet assemblies may deviate from being parallel to each other. In other words, magnets of each of the system's magnet assemblies may enclose an opening angle. For example, at least one of the magnets may deviate from being parallel to the magnet assembly's center axis or symmetry axis by an angle of more greater than or equal to about 3°. The at least one magnet may deviate from being parallel to the center axis or symmetry axis by an angle of less than or equal to about 30°.

For example, when depositing a TCO layer, the material may have to be deposited on a highly sensitive layer. For some materials, particularly transparent conductive oxides or metal oxides, soft deposition via conventional technology like evaporation may be impossible. Embodiments of the present disclosure employ a facing target design to solve this. By using rotary targets, in line with embodiments of the present disclosure, target surface contamination may be mitigated and system up-times may be increased. Further, via the soft deposition as described herein, a number of high-energy particles, like sputter particles, negative ions, and electrons impinging on substrate 502C may be reduced. A change of a temperature on or near the surface of substrate 502C may be reduced. For example, a lower temperature on or near the surface of substrate 502C may be achieved.

The method can further include second deposition on top of the first deposition. For example, the second deposition provides material to a region above the material provided via the first deposition. The term “above” refers to a configuration where substrate 502C is located below the material provided via the first deposition. Generally, at least one further deposition may be provided between the first and the second deposition. During the at least one further deposition, the plasma confinement directions and the size of the aperture can be different than during the first and/or the second deposition. In embodiments, the second deposition may be provided directly on top of the first deposition.

FIG. 5D illustrates an example configuration during the second deposition. The second deposition can include sputtering from rotary targets 510C and 520C through aperture 515C. First magnet assembly 512C can provide plasma confinement 514C in a third direction. Second magnet assembly 522C can provide plasma confinement 514C in a fourth direction. At least one of the third or the fourth direction deviate from being parallel to the substrate plane by an angle of at least a second value, the second value being larger than the first value.

In some embodiments, aperture 515C is greater than or equal to a second size. The second size can be larger than the first size. The second size can range from about 50 mm to about 180 mm. For example, aperture 515C may have a size of about 140 mm. Sputtering through aperture 515C having a larger size can lead to an increased deposition rate. For example, the first size is associated with a first surface area of aperture 515C, and the second size is associated with a second surface area of aperture 515C. More particularly, the second surface area is larger than the first surface area. In some embodiments, as mentioned above, at least one of the third or the fourth direction may deviate from being parallel to the substrate plane by an angle of at least a second value. The second value can range from about 15° to about 70°. The first value particularly relates to the first and the second direction, as defined above. The third and the fourth direction may both deviate from being parallel to the substrate plane by an angle of at least the second value. As shown in FIG. 5D, the third and the fourth direction may deviate from being parallel to the substrate plane by an angle of about 60°. Generally, the directions may deviate from being parallel to the substrate plane by an angle that ranges from about 500 to about 70°. The directions may deviate from being parallel to the substrate plane by an angle of less than about 100°.

By changing the plasma confinement directions, i.e. the directions the plasma confinements are provided in, a deposition rate may be increased. A plasma confinement direction can be changed particularly by changing a position of the magnet assembly providing the plasma confinement, more particularly by rotating the magnet assembly. Changing the plasma confinement directions can also be understood as changing the sputter direction. The aperture size may be increased simultaneously with the change of the plasma confinement directions. By increasing a size of the aperture, the deposition rate may be increased.

When the plasma confinement directions have a large component facing substrate 502C, a homogeneity of the deposition rate may be relatively high, for example as compared to when the plasma confinement directions are facing each other in a direction parallel to the substrate. When the plasma confinement directions have a large component facing substrate 502C, material may be deposited with an even thickness, particularly even without limiting the aperture size to small values. A high deposition rate can be achieved without compromising the thickness distribution of the deposited material.

In some embodiments, the plasma confinement directions of magnet assemblies 512C and 522C are changed gradually or stepwise between the first and the second deposition. For example, positions of magnet assemblies 512C and 522C can be changed gradually or stepwise between the first and the second deposition. During a change of the plasma confinement directions, material may be deposited, particularly continued to be deposited, on substrate 502C. The size of aperture 515C may be changed, particularly increased, simultaneously with the change of the plasma confinement directions.

FIG. 5E shows a system 500E for depositing a material on a solar cell device, according to some embodiments. A first rotary target 510E and a second rotary target 520E are positioned in a deposition chamber 552E. A first additional chamber and a second additional chamber may be provided adjacent to the deposition chamber. According to some embodiments, which can be combined with other embodiments described herein, depositing a material over the substrate can be provided with a dynamic deposition process. For example, the substrate can move past the first rotary target and the second rotary target while material is deposited as indicated by arrow 505E. The deposition chamber or regions of a vacuum processing system may be separated from further chambers or other regions by a valve.

The substrate 502E is provided on a substrate carrier 504E. Within the deposition chamber, rollers 594E may be provided for transport of the substrate carrier 504E into and out of the deposition chamber. An exemplary movement direction of the substrate carrier is indicated by arrow 505E. The term “substrate” as used herein refers to a base structure of a solar cell or a layer stack of a solar cell, on which a further layer is to be deposited with an LDSD process.

The first rotary or rotatable target 510E and the second rotary or rotatable target 520E may both be a cathode. The first and the second rotary or rotatable target may be electrically connected to a DC power supply 580E. For example, one or more anodes 582E and/or a chamber housing can be provided on mass potential. One of more of these components may serve as an anode. In embodiments, which can be combined with other embodiments described herein, at least one or more of the rotary or rotatable targets may be electrically connected to a respective individual power supply. In particular, each of the rotary or rotatable targets may be connected to a respective individual power supply. For example, the first rotary or rotatable target may be connected to a first DC power supply and the second rotary or rotatable target may be connected to a second DC power supply.

As shown in FIG. 5E, the first rotary or rotatable target 510E has a first magnet assembly 512E. The second rotary or rotatable target 520E has a second magnet assembly 522E. The first magnet assembly 512E is positioned within the first rotary or rotatable target 510E. The second magnet assembly 522E is positioned within the second rotary or rotatable target 520E. The rotary or rotatable targets 510E and 520E can be operated to face each other, i.e. such that the magnet assemblies or magnet yokes faces each other. For example, the first magnet assembly 522E provides a first plasma confinement 514E in a first direction facing towards the second rotary or rotatable target and the second magnet assembly 522E provides a second plasma confinement 524E in a second direction facing towards the first rotary or rotatable target.

In the context of the present disclosure, a plasma or plasma confinement is particularly to be understood as a plasma region. A plasma region may be understood as a region where the amount of plasma is increased relative to the environment, particularly due to the effect of a magnetic field of a magnet assembly located in a rotary or rotatable target. For a DC rotatable facing sputter deposition process, the plasma confinement 514E and the plasma confinement 524E can be provided to face a neighboring target. For an AC rotatable facing sputter deposition process, due to the switching of the power supplies, a plasma region, i.e. a single plasma region (e.g., as shown in FIG. 5F) may be provided between neighboring targets, particularly in the event the switching frequency is high enough such that ions might not follow during an oscillation period of the frequency. There may be some wobbling of the plasma region, but the plasma is mainly between neighboring targets as shown in FIG. 5F.

Reverting back to FIG. 5E, during deposition of the material the first magnet assembly 512E within the first rotary or rotatable target provides a first plasma confinement in a first direction facing towards the second rotary or rotatable target. During deposition of the material the second magnet assembly 522E within the second rotary or rotatable target may provide a second plasma confinement in a second direction facing towards the first rotary or rotatable target. The first and the second plasma confinement may overlap at least partially. Typically, the first and the second rotary or rotatable target are neighboring targets. In particular, there are no further targets positioned in a region between the first and the second rotary or rotatable target.

In the context of the present disclosure, providing a plasma confinement in a direction is particularly to be understood as providing the plasma confinement such that a main direction of the plasma confinement is positioned in that direction. Particularly in embodiments where the magnet assembly includes a permanent magnet, providing a plasma confinement in a direction facing a rotary or rotatable target may be understood as providing the magnet assembly at a position such that the magnet assembly faces the rotary or rotatable target, e.g. a neighboring rotary or rotatable target. A sputter yield average direction 516F (see FIG. 5F) is provided such that sputter material is directed from a first rotary or rotatable target with a facing magnet yoke position towards a second rotary or rotatable target.

A rotary or rotatable target according to the present disclosure is particularly to be understood as a rotatable sputtering target. The rotary or rotatable target may be connected to a shaft configured to rotate in at least one operational state of the system. According to embodiments, which can be combined with other embodiments described herein, the rotary or rotatable target is cylindrical.

According to embodiments described herein, an LDSD process for solar cell device fabrication utilizes rotatable facing target sputtering. According to embodiments, which can be combined with other embodiments described herein, the deposition with an LDSD process includes sputtering at least a component of a deposition material from a first rotary target with a first magnet assembly and a second rotary target with a second magnet assembly, wherein the first magnet assembly within the first rotary target providing a first plasma confinement in a first direction facing towards the second rotary target, and the second magnet assembly within the second rotary target providing a second plasma confinement in a second direction facing towards the first rotary target.

According to embodiments of LDSD sputtering, particularly with an AC rotatable facing target sputter deposition process, a process includes directing first sputter material from a first rotary target with a facing magnet yoke position towards a second rotary target with a first power supply during a first power cycle and directing second sputter material from a third rotary target with a facing magnet yoke position towards the second rotary target with a second power supply during the first power cycle. The process further includes switching the first power supply and the second power supply from the first power cycle to a second power cycle, directing third sputter material from the second rotary target with a facing magnet yoke position towards the first rotary target, and directing fourth sputter material from the second rotary target with a facing magnet yoke position towards the third rotary target.

In embodiments, RFTS systems provide magnet yoke positions to have plasma confinements and/or magnet yokes facing each other, i.e. one pointing directly or at least partially towards the other. By positioning the magnet yoke so the sputter yield is directed parallel (or nearly parallel, up to 30° deviation) to the substrate, rather than directly at it, damage from particle energy and UV radiation can be reduced. UV radiation may particularly be reduced with apertures as e.g., shown in FIGS. 5A to 5D, wherein apertures may also be used similarly in FIGS. 5E and 5F.

FIG. 5F shows a system 500F for implementing an RFTS process, according to some embodiments. A first rotary target 510F can have a magnet assembly 512F, a second rotary target 520F can have a magnetic assembly 522F including components 523F-1 and 523F-2, and a third rotary target 530F can have a magnet assembly 532F. A magnet assembly, such as a magnet assembly 512F, can be a magnet yoke have a facing magnet yoke position. The magnet assembly 512F results in a first sputter yield direction 515F-1 and a second sputter yield direction 515F-2. The sputter yield directions correspond to main sputter directions, i.e. directions in which the sputter material is directed. The sputter material direction depends on magnet yoke position, e.g. radial or mainly radial sputter direction originating from the target surface at the racetrack. The first sputter yield direction and the second sputter yield direction may deviate by a small angle. In fully facing magnet yoke positions, in which the magnet yokes face each other directly, i.e. parallel to the substrate, the first sputter yield direction and the second sputter yield direction result in e.g. a sputter yield average direction 516F, which is parallel to the substrate plane. The sputter yield average direction 516F depends on and/or corresponds to the magnet yoke position, i.e. the magnet yoke radial position, e.g. parallel to a substrate surface in FIG. 5F. Plasma confinements 514F are also shown.

According to some embodiments, which can be combined with other embodiments described herein, for facing target sputtering, the sputter yield average direction 516F or the magnet yoke position, can be directly facing the neighboring target (parallel to the substrate), can be oriented backward, i.e. away from the substrate, for example up to 30° from the parallel orientation, or can be oriented towards the substrate, for example up to 300 from the parallel orientation.

Accordingly, a facing magnet yoke position can be described as a magnet yoke angular position, in which the sputter yield average direction is parallel to the substrate surface, i.e. the surface to be deposited, and sputter yield average direction deviating from the parallel direction by an angle of 30° or less (away from or towards the substrate), particularly 15° or less (away from or towards the substrate).

According to embodiments that can be combined with any other embodiments described herein, an array of targets may include a plurality of rotary targets or sputter targets, particularly rotary sputter targets. As an example, the array of targets may include a first rotary target, a second rotary target and a third rotary target. According to embodiments, the array of targets may include more than three rotary targets. For example, the array of targets may include four rotary targets, five rotary targets or even six or seven or ten or more rotary targets. According to embodiments of the present disclosure, which can be combined with other embodiments described herein, 3 or more rotary targets can be provided.

The first rotary target, the second rotary target and the third rotary target and/or the respective target supports can be oriented in a substantially horizontal or a substantially vertical orientation. The term “substantially” may be understood to mean that an orientation may deviate from an exact vertical or horizontal orientation by ±5%, particularly by ±10%. Accordingly, horizontal and or vertical sputtering can be performed. For solar cell device fabrication, the orientation may be beneficially substantially horizontal.

Depositing a layer such as a TCO layer on a layer stack of a solar cell device can include directing first sputter material from a first rotary target 510F with a facing magnet yoke position towards a second rotary target 520F with a first power supply 580F during a first power cycle and directing second sputter material from a third rotary target 530F with a facing magnet yoke position towards the second rotary target 520F with a second power supply 580F during the first power cycle. The layer deposition can further include switching the first power supply and the second power supply from the first power cycle to a second power cycle, and directing third sputter material or a third sputter yield average direction from the second rotary target 520F towards the first rotary target 510F. The third plasma may be directed from the second rotary target 520F towards the first rotary target 510F during the second power cycle. The method may further include directing fourth sputter material or a fourth sputter yield average direction from the second rotary target 520F towards the third rotary target 530F.

Switching of the first power supply 580F and the second power supply 580F may be synchronized. Switching of the first power supply and the second power supply as indicated by arrows 570F may include switching electric poles of the first power supply and switching electric poles of the second power supply. For example, switching of the first power supply and the second power supply, e.g. switching electric poles of the respective first and/or second power supply, may be performed at the same time, i.e. at the same time point. According to some embodiments, which can be combined with other embodiments described herein, a switching frequency of the power supplies can be, for example, 1 Hz to 1 MHz and particularly of 1 kHz to 150 kHz.

The first rotary target and the second rotary target may be connected to a first power supply 580F. The second rotary target and the third rotary target may be connected to a second power supply 580F. When the array of targets includes more than three rotary targets each having a magnet unit, i.e. n rotary targets or a plurality of rotary targets, the number of power supplies is n−1 or a plurality of power supplies. Accordingly, power can be provided to the rotary targets such that the first group of rotary targets acts as a cathode during the first power cycle and the second group of rotary targets acts as an anode during the first power cycle. Further, the first group of rotary targets acts as an anode during the second power cycle and the second group of rotary targets acts as a cathode during the second power cycle. RTFS processes and systems according to embodiments described exemplarily with respect to FIG. 5F may be utilized for depositing layers of a solar cell device, particularly a tandem solar cell device. For example, a TCO layer may be deposited over an active layer such as a perovskite active layer. RTFS processes may further be utilized to deposit other layers, such as an HTL or ETL. Each target is alternatingly either a cathode or anode for each adjacent opposite target. An AC or bipolar discharge can drive either two independent opposite racetracks per target or even a single racetrack. The AC or bipolar discharge enables a better target utilization control as well as an access to dielectric material deposition or deposition of materials with a low electrical conductivity, such as HTLs. Embodiments of the present disclosure can increase the deposition efficiency of target areas used for LDSD applications.

Methods for fabricating solar cell devices (e.g., tandem solar cell devices), such as those performed using systems 500A, 500B, 500C, 500D, 500E and/or 500F, will now be described below with reference to FIGS. 6A-6B.

FIG. 6A is a flowchart of a method 600A for fabricating solar cell devices (e.g., tandem solar cell devices) in a manner that reduces active layer damage as compared to traditional techniques for forming solar cell devices, in accordance with some embodiments. Method 600A can be performed by a system including a processing chamber communicable coupled to a controller that can include hardware (e.g., processing device, circuitry, dedicated logic, programmable logic, microcode, hardware of a device, integrated circuit, etc.), software (e.g., instructions run or executed on a processing device), or a combination thereof. In some implementations, method 600A is performed by one or more components of systems of FIGS. 5-5E. Although shown in a particular sequence or order, unless otherwise specified, the order of the processes can be modified. Thus, the illustrated implementations should be understood only as examples, and the illustrated processes can be performed in a different order, and some processes can be performed in parallel. Additionally, one or more processes can be omitted in various implementations. Thus, not all processes are required in every implementation. Other process flows are possible.

At operation 610A, a base structure of a solar cell device is obtained and, at operation 620A, at least one layer is formed on the base structure using an LDSD process. In some embodiments, the solar cell device is a tandem solar cell device. In some embodiments, the LDSD process is a process performed by the system described above with reference to FIGS. 5A-F.

In some embodiments, the base structure includes a stack of layers including an ETL of a solar cell, and forming at least one layer on the base structure using the LDSD process includes forming a TCO layer on the stack of layers including the ETL. The stack of layers can further include the ETL disposed on an active layer, and the active layer disposed on an HTL. In some embodiments, the solar cell is a perovskite solar cell, then the active layer includes a perovskite layer. For example, the TCO layer can include at least one of: IZO, ITO, ICO, AZO, etc. In some embodiments, forming the at least one layer of the base structure using the LDSD process includes at least one of: ETL or an HTL.

In some embodiments, the base structure includes a stack of alternating semiconductor layers of a solar cell, and forming a TCO layer on the base structure using the LDSD process includes forming the TCO layer on the stack of alternating semiconductor layers. For example, the solar cell can be an HJT solar cell.

In some embodiments, the base structure includes a first solar cell and a set of electrodes disposed on the first solar cell (e.g., on a TCO layer of the first solar cell), and forming a TCO layer on the base structure using the LDSD process includes forming the TCO layer on the first solar cell. For example, the first solar cell can be a bottom solar cell of the tandem solar cell device. In some embodiments, the first solar cell is an HJT solar cell. More specifically, the TCO layer formed on the first solar cell can correspond to a recombination layer upon which a second solar cell of the tandem solar cell device can be formed. For example, the second solar cell can be a top solar cell of the tandem solar cell device. In some embodiments, the second solar cell includes a stack of layers including an ETL (e.g., a perovskite solar cell).

In some embodiments, obtaining the base structure at operation 610A includes receiving the base structure within a processing chamber. For example, the base structure can be placed on a carrier (e.g., hollow carrier) and the carrier holding the base structure can be placed within the processing chamber. In some embodiments, a robot apparatus places the base structure in the processing chamber (e.g., the carrier holding the base structure). In some embodiments, forming the at least one layer at operation 620A includes initiating the LDSD process. For example, a controller communicably coupled to the processing chamber can initiate the LDSD process.

For manufacturing a TCO layer or another layer of a solar cell device according to embodiments described herein, the solar cell device or a plurality of solar cell devices can be supported by a carrier.

Forming a layer using the LDSD process can include directing first sputter material from a first rotary target with a facing magnet yoke position towards a second rotary target and e.g. directing second sputter material from a third rotary target with a facing magnet yoke position towards the second rotary target. Forming a layer using the LDSD process can further include directing third sputter material from the second rotary target with a facing magnet yoke position towards the first rotary target, and directing fourth sputter material from the second rotary target with a facing magnet yoke position towards the third rotary target.

A process of depositing a layer (e.g., using an RFTS process with AC, DC or bipolar sputtering), can include directing first sputter material from a first rotary target with a facing magnet yoke position towards a second rotary target with a first power supply during a first power cycle and directing second sputter material from a third rotary target with a facing magnet yoke position towards the second rotary target with a second power supply during the first power cycle. The process further includes switching the first power supply and the second power supply from the first power cycle to a second power cycle, directing third sputter material from the second rotary target with a facing magnet yoke position towards the first rotary target, and directing fourth sputter material from the second rotary target with a facing magnet yoke position towards the third rotary target.

More specifically, the LDSD process can be an RFTS process. RTFS processes can be utilized on large processing areas corresponding for example to substrate generation sizes of display manufacturing applications, e.g. GEN 4.5 or above. Individual solar cell devices may have a size of 158 mm×158 mm. Further, larger solar cell device sizes can be up to 166 mm×166 mm or 182 mm×182 mm. Even larger generation sizes may include 210 mm×210 mm or 230 mm×230 mm. The solar cell devices may be provided in a carrier for large area deposition, e.g. GEN 4.5 or more and may be masked in the carrier having a plurality of trays, e.g. with an edge exclusion mask covering an edge of the solar cell device, or may not include mask.

For example, performing the LDSD process can include moving the carrier about a sputtering region to form the TCO layer on the base structure (e.g., on the ETL). Various parameters of the LDSD process can be optimized to form the TCO layer on the base structure, such as magnet angle, target-to-base structure distance, such as gas flow mixture, pressure, magnet yoke direction, aperture openings to meet TCO layer properties (e.g., thickness, sheet resistance, adhesion, stress and/or roughness), etc. The LDSD process can be a low temperature process. In some embodiments, the LDSD process is performed at a temperature of less than or equal to about 80° C. In some embodiments, the LDSD process is performed at a temperature of less than or equal to about 60° C. In some embodiments, the LDSD process is performed at a temperature of less than or equal to about 50° C. In some embodiments, the LDSD process is performed at about room temperature. Various process parameters can be optimized to form TCO layers using the LDSD process.

In some embodiments, performing the LDSD process includes performing a first deposition to deposit a layer (e.g., the TCO layer). The first deposition can include sputtering from a first and a second rotary target through an aperture, the aperture being adjustable and having less than a first size. The first rotary target has a first magnet assembly providing a plasma confinement or a magnet yoke orientation in a first direction facing the second rotary target. The second rotary target has a second magnet assembly providing a plasma confinement or a magnet yoke orientation in a second direction facing the first rotary target. The first direction and the second direction deviate from being parallel to a substrate plane of the substrate by an angle of less than a first value. The method further includes a second deposition on top of the first deposition. The second deposition can include sputtering from the first and the second rotary target through the aperture, the aperture having at least a second size, the second size being larger than the first size. The first magnet assembly provides a plasma confinement or a magnet yoke orientation in a third direction. The second magnet assembly provides a plasma confinement or a magnet yoke orientation in a fourth direction. At least one of the third or the fourth direction deviate from being parallel to the substrate plane by an angle of at least a second value, the second value being larger than the first value.

In some embodiments, performing the LDSD process includes depositing the TCO layer by sputtering from a first rotary target having a first magnet assembly having a first plasma confinement and with an aperture plate and sputtering simultaneously from a second rotary target having a second magnet assembly having a second plasma confinement and with the aperture plate. The first plasma confinement can face the second rotary target and the second plasma confinement can face the first rotary target. The first plasma confinement and the second plasma confinement can provide a plasma region between the first rotary target and the second rotary target having a center line perpendicular to a substrate surface of the substrate. The aperture plate can have a body with a shielding portion configured to shield a region between the plasma region and the substrate at least at the center line.

In some embodiments, to further reduce damage that may occur due to particle bombardment and/or UV irradiation, off-centric sputtering can be used to improve the damage-to-deposit on-rate ratio. Off-centric LDSD blocks the shortest sputter paths between the plasma confinement region and the substrate by an aperture plate having centric positioned shielding portion(s). An off-centric aperture can be provided with respect to the facing targets. An aperture is provided, for example, exclusively provided, for longer sputter paths to reduce the kinetic particle energy and/or to block the most intense UV radiation which is emitted out of the center of the facing target, particularly on a short mean free path.

In some embodiments, the plasma confinement is not directed towards substrate 502, for example at an angle of about 90°, but can be parallel or essentially parallel with a deviation of some degrees, e.g. up to about 30°, away from the base structure or towards substrate 502. The sputtering rate can be lower as compared to magnetron sputtering having a plasma confinement directed towards the substrate. Accordingly, the LDSD process can reduce the damage at a given sputter rate. Further details regarding operations 610A-620A are described above with reference to FIGS. 1-5D and will now be described below with reference to FIG. 6B.

FIG. 6B is a flowchart of a method 600B for fabricating solar cell devices to reduce active layer damage, in accordance with some embodiments. Method 600B can be performed by a system including a processing chamber communicable coupled to a controller that can include hardware (e.g., processing device, circuitry, dedicated logic, programmable logic, microcode, hardware of a device, integrated circuit, etc.), software (e.g., instructions run or executed on a processing device), or a combination thereof. In some implementations, method 600B is performed by one or more components of systems of FIGS. 5-5E. Although shown in a particular sequence or order, unless otherwise specified, the order of the processes can be modified. Thus, the illustrated implementations should be understood only as examples, and the illustrated processes can be performed in a different order, and some processes can be performed in parallel. Additionally, one or more processes can be omitted in various implementations. Thus, not all processes are required in every implementation. Other process flows are possible.

At operation 610B, a base structure of a solar cell device is received. More specifically, the base structure can be received within a processing chamber. For example, the base structure can be placed on a carrier (e.g., hollow carrier) and the carrier holding the base structure can be placed within the processing chamber. In some embodiments, a robot apparatus places the base structure in the processing chamber (e.g., the carrier holding the base structure). In some embodiments, the solar cell device is a tandem solar cell device.

At operation 620B, an LDSD process to form a TCO layer on the base structure is initiated. For example, a controller communicably coupled to the processing chamber can initiate the LDSD process. At operation 630B, the LDSD process to form the TCO layer on the base structure is performed. For example, performing the LDSD process can include moving the carrier about a sputtering region to form the TCO layer on the base structure (e.g., on the ETL). Various parameters of the LDSD process, such as magnet angle and target-to-base structure distance, can be adjusted to optimize the formation of the TCO layer on the base structure.

In some embodiments, the base structure includes a stack of layers including an ETL of a solar cell, and performing the LDSD process to form the TCO layer on the base structure includes forming the TCO layer on the stack of layers including the ETL. The stack of layers can further include the ETL disposed on an active layer, and the active layer disposed on an HTL. In some embodiments, the solar cell is a perovskite solar cell, then the active layer includes a perovskite layer. In some embodiments at least one of the ETL or the HTL is formed using the LDSD process.

In some embodiments, the base structure includes a stack of alternating semiconductor layers of a solar cell, and performing the LDSD process to form the TCO layer on the base structure includes forming the TCO layer on the stack of alternating semiconductor layers. For example, the solar cell can be an HJT solar cell.

In some embodiments, the base structure includes a first solar cell and a set of electrodes disposed on the first solar cell (e.g., on a TCO layer of the first solar cell), and performing the LDSD process to form the TCO layer on the base structure includes forming the TCO layer on the first solar cell. For example, the first solar cell can be a bottom solar cell of the tandem solar cell device. In some embodiments, the first solar cell is an HJT solar cell. More specifically, the TCO layer formed on the first solar cell can correspond to a recombination layer upon which a second solar cell of the tandem solar cell device can be formed. For example, the second solar cell can be a top solar cell of the tandem solar cell device. In some embodiments, the second solar cell includes a stack of layers including an ETL (e.g., a perovskite solar cell).

At operation 640B, fabrication of the solar cell device is completed. For example, completing fabrication of the solar cell device can include forming a set of electrodes on the TCO layer. As another example, completing fabrication of the tandem solar cell device can include forming a solar cell on the TCO layer (e.g., on the recombination layer), and forming a set of electrodes on the solar cell. In some embodiments, the solar cell formed on the TCO layer includes a stack of layers including an ETL disposed on an active layer. For example, the solar cell formed on the TCO layer can be a perovskite solar cell and the active layer can include a perovskite layer. In some embodiments, the ETL is formed using the LDSD process. Further details regarding operations 610B-640B are described above with reference to FIGS. 1-6A.

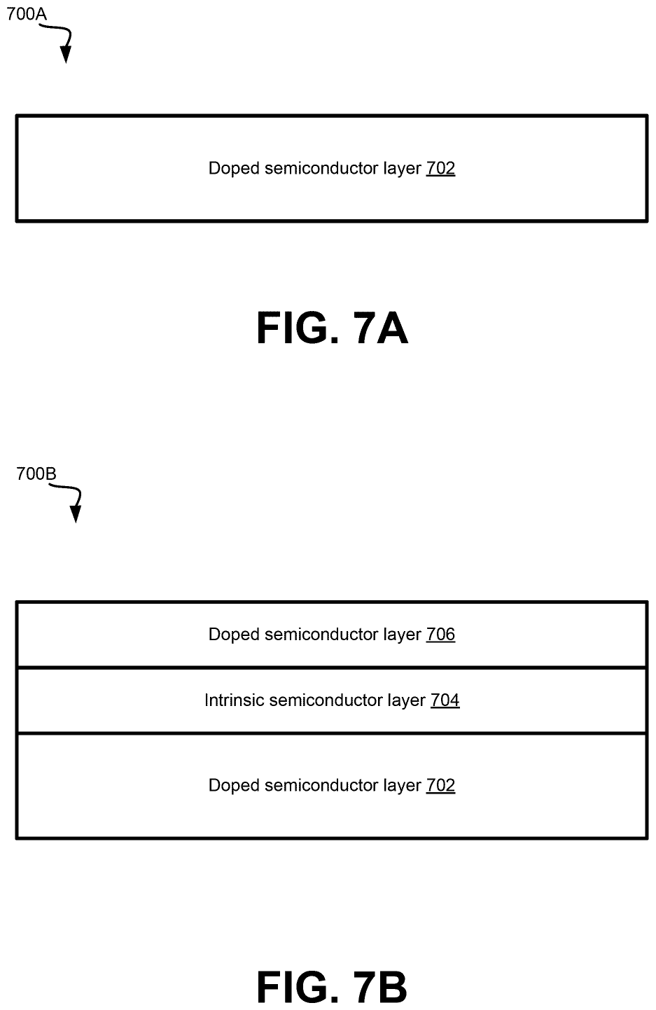

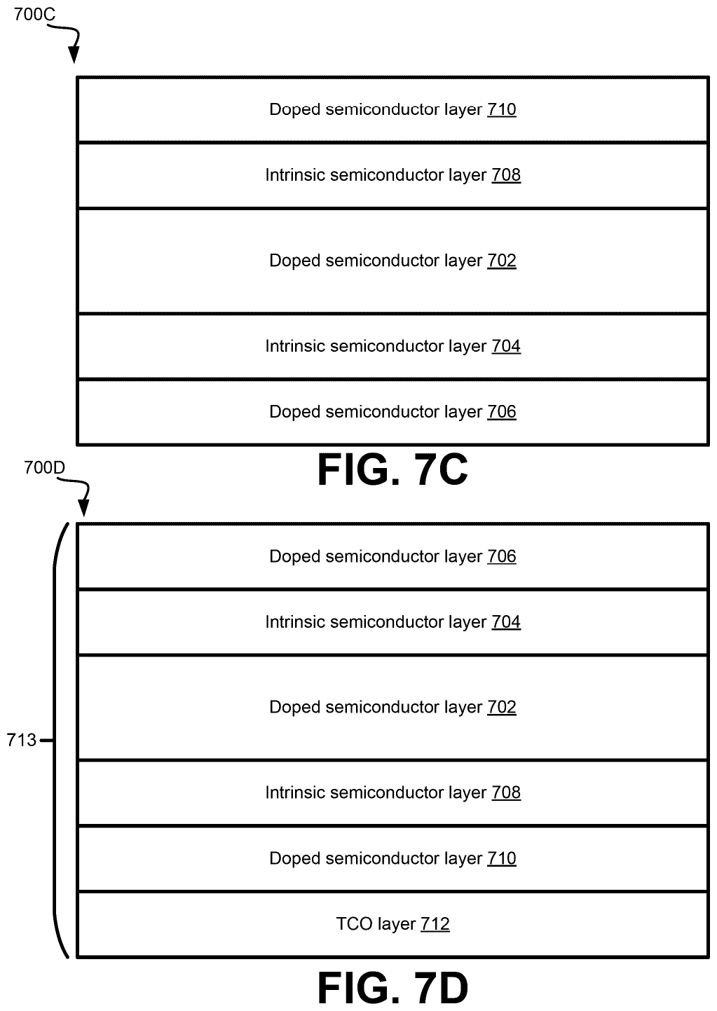

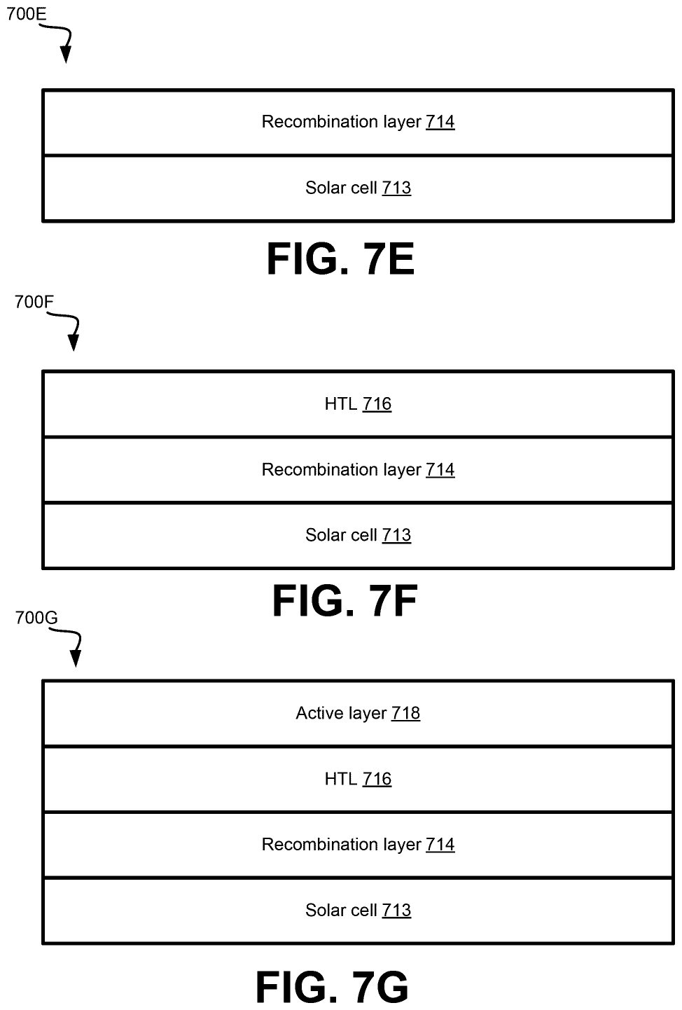

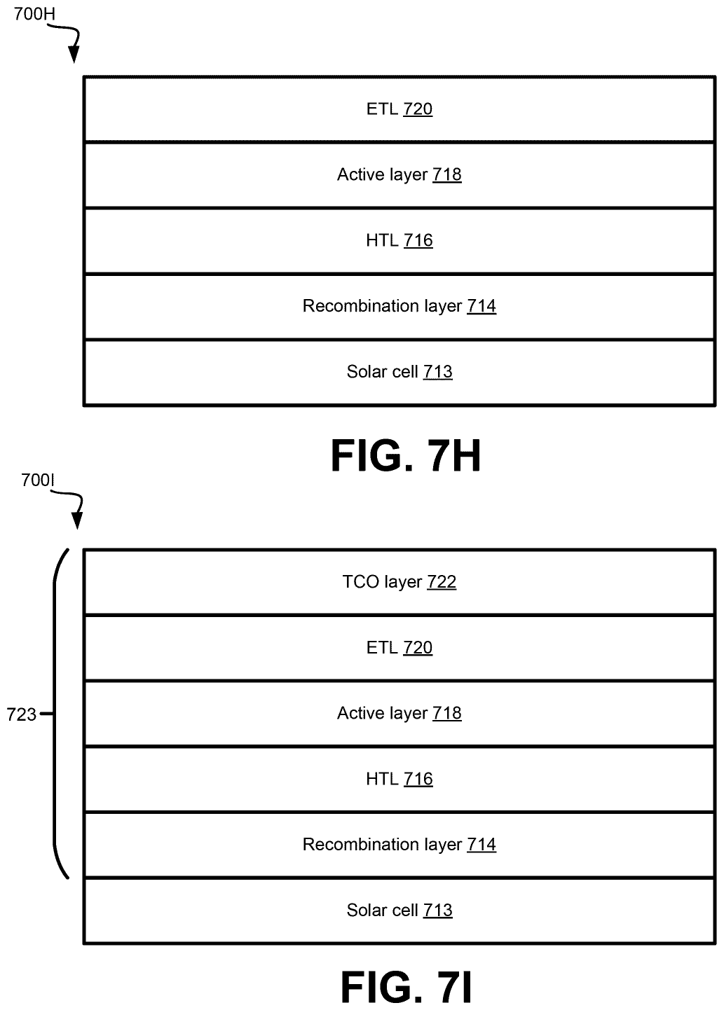

FIGS. 7A-7I are block diagrams illustrating cross-sectional views during the fabrication of solar cell device, particularly a tandem solar device, in accordance with some embodiments. More specifically, FIGS. 7A-7E illustrate the formation of a first solar cell (e.g., bottom solar cell) of the tandem solar cell device, FIG. 7F illustrates the formation of a recombination layer on the first solar cell, and FIGS. 7G-7I illustrate the formation of a second solar cell (e.g., top solar cell) of the tandem solar cell device. In these illustrative examples, the first solar cell includes a stack of alternating semiconductor layers (e.g., an HJT solar cell) and the second solar cell includes a stack of layers including an ETL (e.g., a perovskite solar cell).

FIG. 7A is a diagram 700A showing doped semiconductor layer 702. Doped semiconductor layer 702 can be a substrate of the tandem solar cell device (e.g., wafer). For example, doped semiconductor layer 702 can be similar to doped semiconductor layer 330 described above with reference to FIG. 3. Doped semiconductor layer 702 can be processed by performing wafer texturing and/or cleaning. Further details regarding doped semiconductor layer 702 are described above with reference to FIG. 3.

FIG. 7B is a diagram 700B showing the formation of intrinsic semiconductor layer 704 on doped semiconductor layer 702, and doped semiconductor layer 706 on intrinsic semiconductor layer 704, resulting in a first intermediate structure. For example, intrinsic semiconductor layer 704 can be similar to intrinsic semiconductor layer 320 described above with reference to FIG. 3, and doped semiconductor layer 706 can be similar to doped semiconductor layer 310 described above with reference to FIG. 3. Layers 704 and 706 can be formed using any suitable processes. For example, layers 704 and 706 can be formed using a CVD process. Further details regarding layers 704 and 706 are described above with reference to FIG. 3.

FIG. 7C is a diagram 700C showing, after flipping the first intermediate structure, the formation of intrinsic semiconductor layer 708 on doped semiconductor layer 702, and doped semiconductor layer 710 on intrinsic semiconductor layer 708, resulting in a second intermediate structure. For example, intrinsic semiconductor layer 708 can be similar to intrinsic semiconductor layer 340 described above with reference to FIG. 3, and doped semiconductor layer 710 can be similar to doped semiconductor layer 350 described above with reference to FIG. 3. Layers 708 and 710 can be formed using any suitable processes. For example, layers 708 and 710 can be formed using a CVD process. Further details regarding layers 708 and 710 are described above with reference to FIG. 3.

FIG. 7D is a diagram 700D showing, after flipping the second intermediate structure, the formation of TCO layer 712 underneath doped semiconductor layer 710, resulting in solar cell 713. TCO layer 712 can be similar to TCO layer 302 described above with reference to FIG. 3. More specifically, TCO layer 712 can be formed using a back-side deposition process. In some embodiments, TCO layer 712 is formed using a PVD process. In some embodiments, TCO layer 712 is formed using an LDSD process. In some embodiments, solar cell 713 is an HJT solar cell. Further details regarding TCO layer 712 are described above with reference to FIG. 3.

FIG. 7E is a diagram 700E showing the formation of recombination layer 714 on solar cell 713. For example, recombination layer 714 can include a TCO layer. Recombination layer 714 can be similar to recombination layer 402 described above with reference to FIG. 4A. More specifically, recombination layer 714 can be formed using a front-side deposition process. In some embodiments, recombination layer 714 is formed using a PVD process. In some embodiments, recombination layer 714 is formed using an LDSD process. Further details regarding recombination layer 714 are described above with reference to FIG. 4A.

FIG. 7F is a diagram 700F showing the formation of HTL 716 on recombination layer 714. HTL 716 can be similar to HTL 230 described above with reference to FIG. 2A. HTL 716 can be formed using any suitable process. In some embodiments, HTL 716 is formed using an evaporation process. Further details regarding HTL 716 are described above with reference to FIG. 2A.

FIG. 7G is a diagram 700G showing the formation of active layer 718 on HTL 716 on recombination layer 714. Active layer 718 can be similar to active layer 220 described above with reference to FIG. 2A. In some embodiments, active layer 718 includes a perovskite layer. In some embodiments, active layer 718 includes a buffer layer disposed on the perovskite layer. Active layer 718 can be formed using any suitable process. In some embodiments, forming active layer 718 includes forming the perovskite layer using an evaporation process. In some embodiments, forming active layer 718 includes forming the perovskite layer using a CVD process. In some embodiments, forming active layer 718 includes forming the perovskite layer using a printing process. forming active layer 718 includes forming the buffer layer using an ALD process. Further details regarding active layer 718 are described above with reference to FIG. 2A.

According to some embodiments, which can be combined with other embodiments described herein, the buffer layer between the active layer and that TCO may also be avoided due to utilizing and RTFS process for LDSD deposition.

FIG. 7H is a diagram 700H showing the formation of ETL 720 on active layer 718. ETL 720 can be similar to ETL 210 described above with reference to FIG. 2A. ETL 720 can be formed using any suitable process. In some embodiments, ETL 720 is formed using an evaporation process. Further details regarding ETL 720 are described above with reference to FIG. 2A.

According to some embodiments, which can be combined with other embodiments described herein, and ETL may be deposited on the active layer utilizing and RTFS process for LDSD deposition.

FIG. 7I is a diagram 700I showing the formation of TCO layer 722 on ETL 720, resulting in solar cell 723. TCO layer 722 can be similar to TCO layer 202 described above with reference to FIG. 2A. TCO layer 722 can be formed using any suitable process. In some embodiments, TCO layer 722 is formed using an LDSD process. In some embodiments, TCO layer 722 is formed using a PVD process. In some embodiments, solar cell 723 is a perovskite solar cell. Further details regarding TCO layer 722 are described above with reference to FIG. 2A. A first set of electrodes can be formed on solar cell 713 and a second set of electrodes can be formed on solar cell 723 (e.g., electrodes 410-1 through 410-4 as shown in FIG. 4A). The first and second sets of electrodes can be formed using any suitable process. In some embodiments, the first and second sets of electrodes are formed using a printing process. Further details regarding the first and second sets of electrodes are described above with reference to FIG. 4A.

Some tandem solar cell devices, such a tandem solar cell device including a solar cell having ETLs disposed on active layers, can suffer from performance and/or efficiency degradation if the active layer is exposed to atmospheric conditions (e.g., moisture and/or oxygen). For example, an active layer can be a perovskite layer. Encapsulation techniques can be used to improve long-term stability and extend the lifetime of such tandem solar cell devices. Some approaches to encapsulation are module-level with respect to a module of tandem solar cell devices. Generally, a module refers to an assembly of multiple solar cell devices that work together to generate electricity from sunlight. For example, a module can be embodied as a solar panel.

Some modules can be encapsulated using glass-to-glass encapsulation. Glass-to-glass encapsulation includes encapsulating a module using two sheets of glass with an encapsulant. The glass sheets can be formed from a glass material that is resistant to breakage and can withstand various temperatures and weather conditions, such as tempered glass. The encapsulant between the glass sheets can provide adhesion and protect the solar cells of the module from air and moisture. In some implementations, the encapsulant can include a polymer material. For example, the polymer material can include ethylene vinyl acetate (EVA), polyisobutylene (PIB), butyl rubber, an epoxy resin, etc.

Water vapor is a primary factor that degrades the performance of some solar cells (e.g., perovskite solar cells). Water vapor transmission rate (WVTR) is a measure of the amount of water vapor that passes through a material over a period of time. That is, the WVTR of a material is a metric related to the ability of the material to function as a barrier against water. A higher WVTR means that the material is more permissible to water vapor, which can lead to electronic device degradation. Some module-level encapsulation methods, such as glass-to-glass encapsulation, can enable WVTRs that range from about 101 grams per square meter per day (g/m²/day) to about 10⁻³ g/m²/day (e.g., measured at a temperature of about 85° C.±10% and a humidity of about 85%±10%). However, components such as perovskite layers may have lower WVTR requirements of less than or equal to about 10⁻³ g/m²/day that cannot be realized by using module-level encapsulation such as glass-to-glass encapsulation. Additionally, the efficiency of solar cells that employ module-level encapsulation (e.g., glass-to-glass encapsulation) can be shown during temperature cycle testing to rapidly degrade over time.

To address these and other drawbacks, embodiments described herein provide for fabrication of tandem solar cell devices using device-level encapsulation. A tandem solar cell device described herein can include any number of solar cells in accordance with embodiments described herein. In some embodiments, a tandem solar cell device is a two-cell device including a first solar cell and a second solar cell disposed on the first solar cell. A recombination layer can be disposed between the first solar cell and the second solar cell. For example, a tandem solar cell device can be a perovskite/HJT tandem solar cell device, a perovskite/perovskite tandem solar cell device, etc. In some embodiments, a tandem solar cell device is a triple cell device including a first solar cell, a second solar cell disposed on the first solar cell, and a third solar cell disposed on the second solar cell. For example, a tandem solar cell device can be a perovskite/perovskite/HJT tandem solar cell device.

At least one device-level encapsulation layer can be performed to encapsulate at least one tandem solar cell device, respectively. A device-level encapsulation layer is a discrete encapsulation layer formed on a respective tandem solar cell device. More specifically, a device-level encapsulation layer is a discrete encapsulation layer formed along an upper surface and side surfaces of a respective tandem solar cell device. For example, a device-level encapsulation layer is a layer of encapsulation material that is conformally deposited along the upper and side surfaces of a respective tandem solar cell device.

A device-level encapsulation layer can be used to protect the active layer of a solar cell of a tandem solar cell device (e.g., perovskite layer) to air and moisture conditions. The device-level encapsulation layer can be formed from a material that provides a suitably low WVTR to protect the active layer from moisture. In some embodiments, the device-level encapsulation layer provides a WVTR that is greater than 10⁻³ g/m²/day (e.g., measured at a temperature of about 85° C.±10% and a humidity of about 85%±10%). Examples of materials that can be used to form the device-level encapsulation layer include aluminum oxide (Al₂O₃), silicon nitride (SiNₓ), silicon oxynitride (SiON), silicon carbonitride (SiCN), hexamethyldisiloxane (HMDSO), etc. In some embodiments, a device-level encapsulation layer is formed using thin film encapsulation (TFE). TFE can be performed to form the encapsulation layer using any suitable deposition process. In some embodiments, TFE is performed using chemical vapor deposition (CVD).

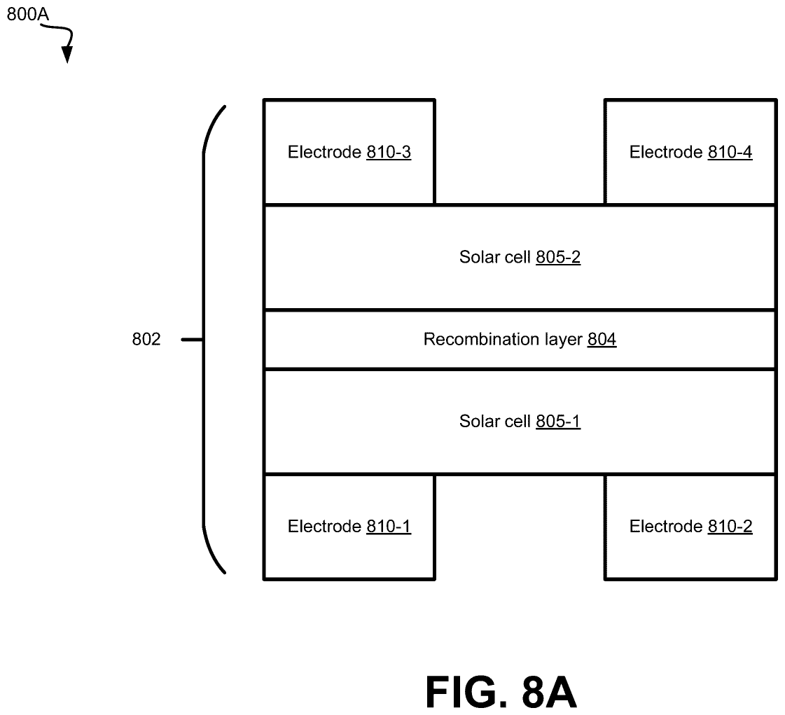

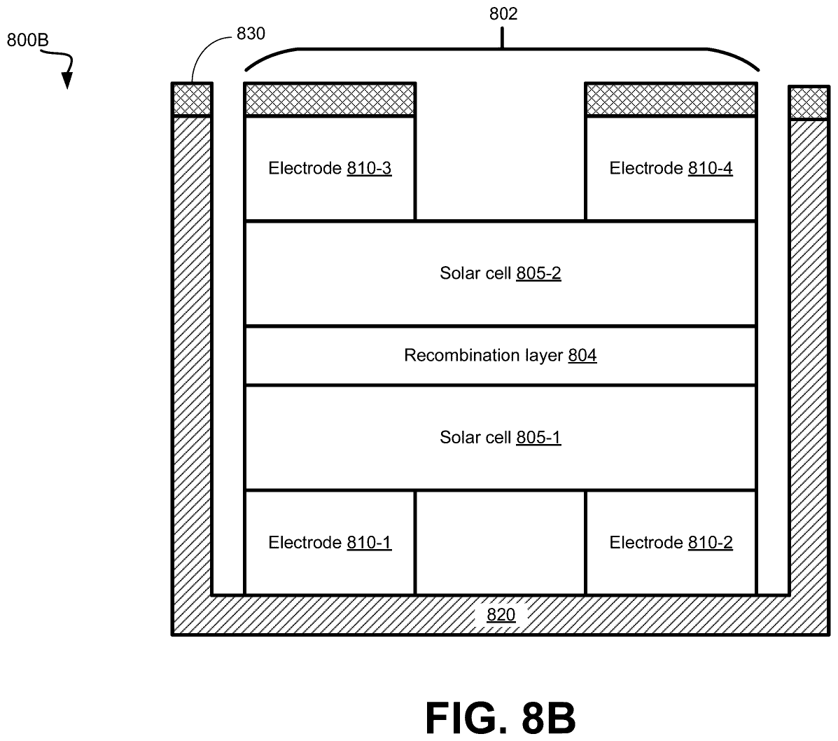

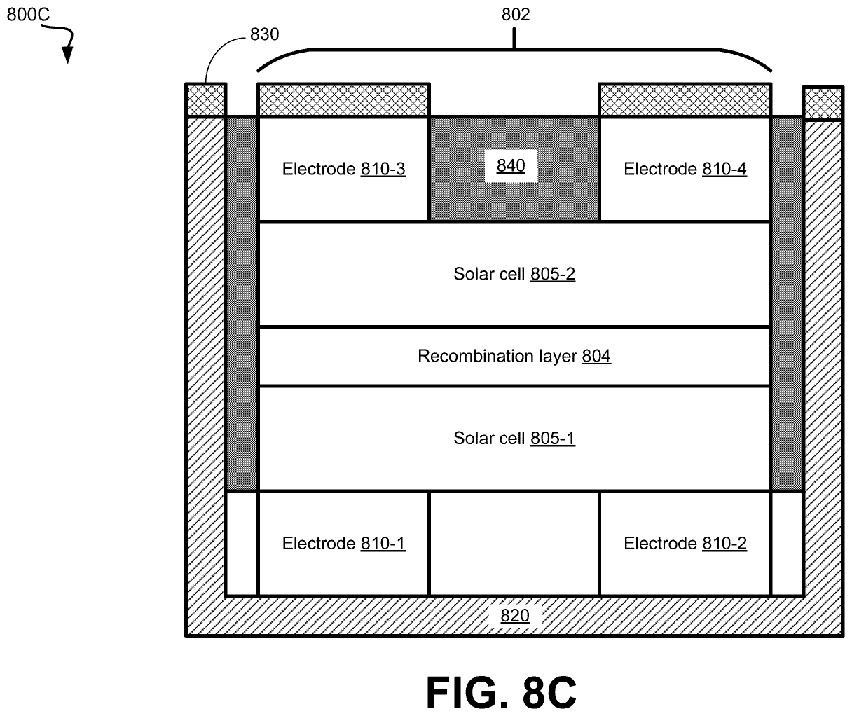

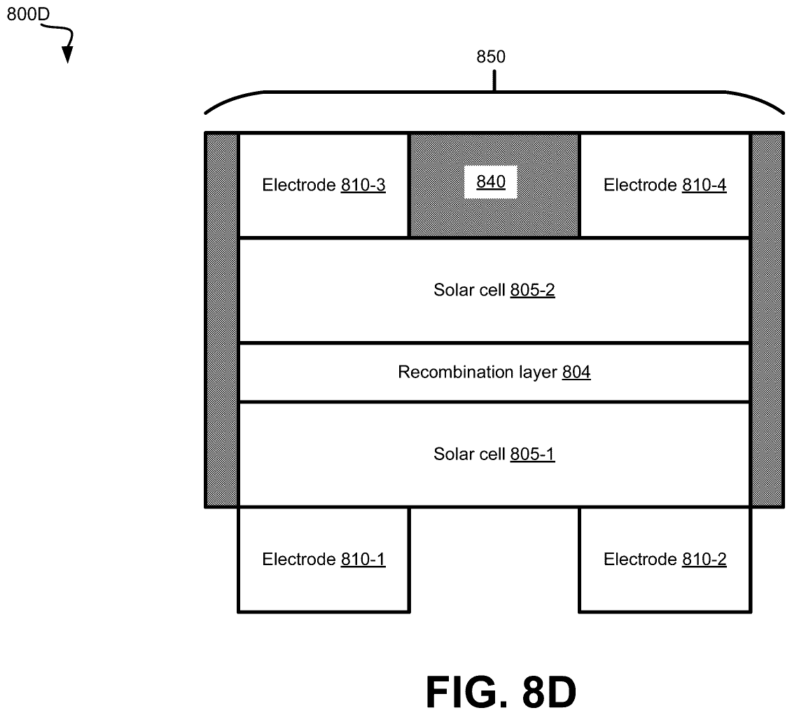

In some embodiments, the at least one tandem solar cell device includes a plurality of solar cell devices. A module can be formed from the plurality of tandem solar cell devices, in which each tandem solar cell device is electrically connected. In some embodiments, module-level encapsulation can be performed to encapsulate, in addition to the device-level encapsulation performed to encapsulate each tandem solar cell device within the module (i.e., a hybrid encapsulation method). In some embodiments, performing module-level encapsulation includes performing glass-to-glass encapsulation. Further details regarding fabricating tandem solar cell devices using device-level encapsulation will now be described below with reference to FIGS. 8A-10B.

FIGS. 8A-8D are diagrams of cross-sectional views illustrating the fabrication of a tandem solar cell device to reduce active layer damage, in accordance with some embodiments. More specifically, FIGS. 8A-8D illustrate the fabrication of a tandem solar cell device using device-level encapsulation. For example, FIG. 8A is a diagram 800A illustrating tandem solar cell device 802. For example, at least a portion of tandem solar cell device 802 can be formed using an LDSD process, as described above with reference to FIGS. 1-7I. In this illustrative example, tandem solar cell device 802 is a two-cell device. However, tandem solar cell device 802 can include any suitable number of solar cells. In some embodiments, tandem solar cell device 802 is a triple cell device.

As shown, tandem solar cell device 802 can include solar cell 805-1 and solar cell 805-2, recombination layer 804 disposed between solar cell 405-1 and solar cell 805-2, electrodes 810-1 and 810-2 disposed on solar cell 805-1, and electrodes 810-3 and 810-4 disposed on solar cell 805-2. Recombination layer 804 can facilitate recombination of electrons and holes. In some embodiments, recombination layer 804 is a TCO layer. For example, recombination layer 804 can include ITO, IZO, ICO, AZO, etc. Electrodes 810-1 through 810-4 can include any suitable material. For example, electrodes 810-1 through 810-4 can include Ag. In some embodiments, solar cell 805-1 includes a stack of alternating semiconductor layers. For example, solar cell 805-1 can be an HJT solar cell. Further details regarding solar cell 805-1 are described above with reference to FIGS. 3-7D. In some embodiments, solar cell 405-2 includes a stack including an ETL disposed on an active layer. For example, solar cell 405-2 can be a perovskite solar cell and the active layer can be a perovskite layer. Further details regarding solar cell 405-2 are described above with reference to FIGS. 2, 4-6B and 7F-7I.

FIG. 8B is a diagram 800B illustrating the placement of tandem solar cell device 802 within tray 820 within a processing chamber, and the formation of mask layers 830 on the upper surfaces of electrodes 810-3 and 810-4 and tray 820. In some embodiments, tray 820 is a CVD tray and the processing chamber is a CVD chamber. Mask layers 830 can include any suitable material that can prevent the formation of encapsulation layer material on the upper surface of electrodes 810-3 and 810-4 and tray 820. In some embodiments, mask layers 830 correspond to a self-aligned mask. A self-aligned mask is designed to align itself to a substrate during a deposition process. This can be done by using a set of alignment marks on the mask and substrate that are precisely positioned relative to each other.

FIG. 8C is a diagram 800C illustrating the formation of encapsulation layer 840 within the processing chamber, and FIG. 8D is a diagram 800D illustrating the removal of mask layers 830 after the forming of encapsulation layer 840, resulting in encapsulated tandem solar cell device 850. More specifically, encapsulation layer 840 provides device-level encapsulation of tandem solar cell device 802. For example, as shown, encapsulation layer 840 can be formed on the top and side surfaces of tandem solar cell device 802. Encapsulation layer 840 can be formed from a material that provides a suitably low WVTR to protect the active layer from moisture. In some embodiments, encapsulation 840 provides a WVTR that is greater than 10⁻³ g/m²/day (e.g., measured at a temperature of about 85° C.±10% and a humidity of about 85%±10%). Examples of materials that can be used to form encapsulation layer 840 include Al₂O₃, SiNₓ, SiON, SiCN, HMDSO, etc. In some embodiments, encapsulation layer 840 is formed using TFE. TFE can be performed to form encapsulation layer 840 using any suitable deposition process. In some embodiments, TFE is performed using CVD.

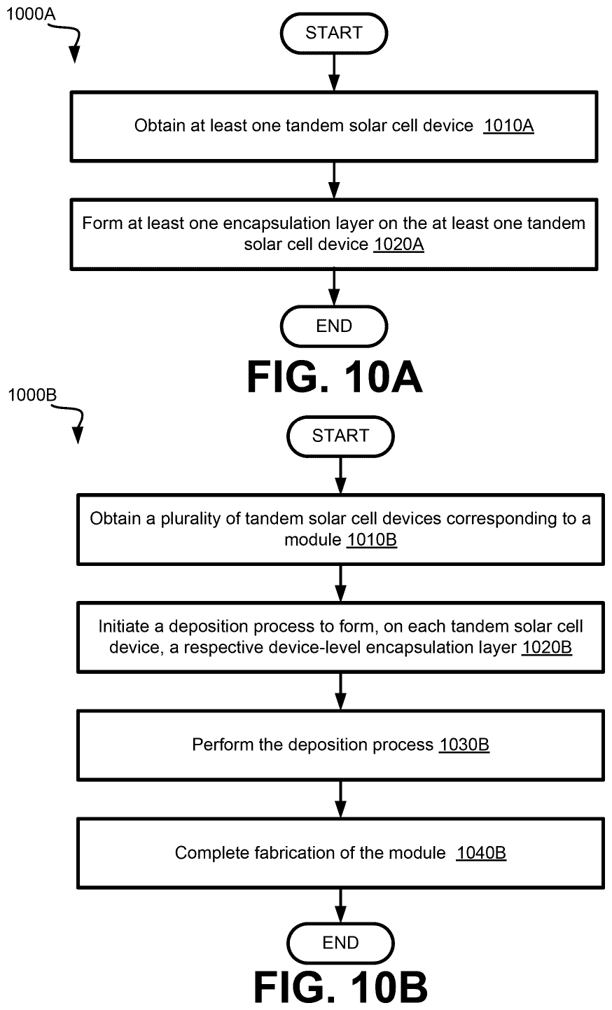

In some embodiments, multiple device-level encapsulation layers including encapsulation layer 840 are formed as separate encapsulation layers on respective tandem solar cell devices. In some embodiments, the multiple device-level encapsulation layers are formed simultaneously during a deposition process (e.g. TFE process). In some embodiments, at least one device-level encapsulation layer is formed during a separate deposition process. Further details regarding the method of fabricating device 850 will be described below with reference to FIGS. 10A-10B.

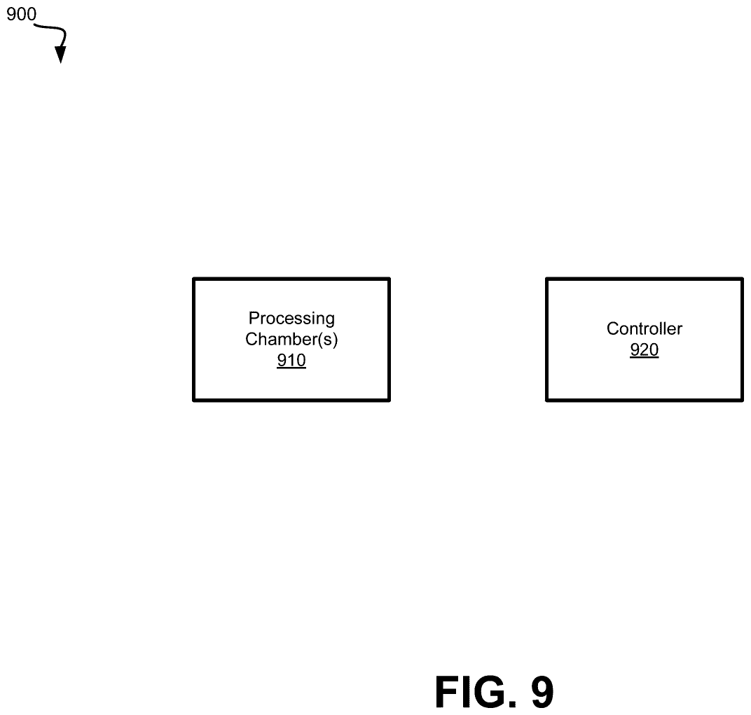

FIG. 9 is a diagram of a system 900 for fabricating an electronic device to reduce active layer damage, in accordance with some embodiments. System 900 can include at least one processing chamber 910 communicably coupled to controller 920. In some embodiment, at least one processing chamber 910 includes a CVD chamber. System 900 can be used to perform device-level encapsulation of at least one tandem solar cell device. For example, at least a portion of the at least one tandem solar cell device can be formed using an LDSD process, as described above with reference to FIGS. 1-8D. In some embodiments, a tandem solar device includes a first solar cell and a second solar cell. For example, the first solar cell can be a top solar cell and the second solar cell can be a bottom solar cell. For example, the first solar cell can include an ETL (e.g., a perovskite solar cell) and the second solar cell can be an HJT solar cell. Methods for fabricating electronic devices using the processing chamber will now be described below with reference to FIGS. 10A-10B.

FIG. 10A is a flowchart of a method 1000A for fabricating tandem solar cell devices to reduce active layer damage, in accordance with some embodiments. More specifically, FIG. 10A illustrates the fabrication of a tandem solar cell device using device-level encapsulation. Method 1000A can be performed by a system including a processing chamber communicable coupled to a controller that can include hardware (e.g., processing device, circuitry, dedicated logic, programmable logic, microcode, hardware of a device, integrated circuit, etc.), software (e.g., instructions run or executed on a processing device), or a combination thereof. In some implementations, method 1000A is performed by one or more components of system 900 of FIG. 9. Although shown in a particular sequence or order, unless otherwise specified, the order of the processes can be modified. Thus, the illustrated implementations should be understood only as examples, and the illustrated processes can be performed in a different order, and some processes can be performed in parallel. Additionally, one or more processes can be omitted in various implementations. Thus, not all processes are required in every implementation. Other process flows are possible.

At operation 1010A, at least one tandem solar cell device is obtained. For example, at least a portion of the at least one tandem solar cell device can be formed using an LDSD process, as described above with reference to FIGS. 1-7I. In some embodiments, the at least one tandem solar cell device includes a plurality of solar cell devices. For example, the plurality of solar cell devices can correspond to a module. Each tandem solar cell device can include at least a first solar cell and a second solar cell. In some embodiments, a tandem solar cell device is a two-cell device. For example, the first solar cell can be a bottom solar cell and the second solar cell can be a top solar cell. In some embodiments, a recombination layer is disposed between the first solar cell and the second solar cell. For example, the recombination layer can be a TCO layer. In some embodiments, the first solar cell includes a stack of alternating semiconductor layers disposed on a TCO layer. For example, the solar cell can be an HJT solar cell. In some embodiments the second solar cell includes a stack of layers including an ETL disposed on an active layer, and a TCO layer disposed on the ETL. Additionally, the active layer can be disposed on an HTL. In some embodiments, the solar cell is a perovskite solar cell, then the active layer includes a perovskite layer. In some embodiments, a tandem solar cell device is a triple cell device.

In some embodiments, obtaining the substrate at operation 1010A includes receiving the at least one tandem solar cell device within a processing chamber that can form the at least one encapsulation layer using TFE. For example, the at least one tandem solar cell device can be placed in a tray and loaded into the processing chamber. In some embodiments, the processing chamber is a CVD chamber, and the tray is a CVD tray. In some embodiments, a robot apparatus places the substrate in the processing chamber (e.g., the tray). The tray can have any suitable dimensions. In some embodiments, the tray has a width between about 300 mm to about 500 mm and a length between about 400 mm to about 600 mm.

At operation 1020A, at least one encapsulation layer is formed on the at least one tandem solar cell device. Forming the at least one encapsulation layer on at least one tandem solar cell device at operation 1020A can include forming each device-level encapsulation layer on a respective tandem solar cell device. A device-level encapsulation layer is a discrete encapsulation layer formed on a respective tandem solar cell device. More specifically, a device-level encapsulation layer is a discrete encapsulation layer formed along an upper surface and side surfaces of a respective tandem solar cell device. In some embodiments, forming a device-level encapsulation layer on a respective tandem solar cell device includes conformally depositing the device-level encapsulation layer along upper and side surfaces of the respective tandem solar cell device. For example forming a device-level encapsulation layer on a tandem solar cell device can include forming mask layers over respective portions of the tandem solar cell device (e.g., over electrodes) and the tray, and forming the device-level encapsulation layer on exposed portions of the top and side surfaces of the tandem solar cell device. In some embodiments, the mask layers correspond to a self-aligned mask. The mask layers can then be removed from the tandem solar cell device to obtain a device-level encapsulated device. The device-level encapsulation layer can include any suitable material in accordance with embodiments described herein. Examples of materials that can be used to form the device-level encapsulation layer include Al₂O₃, SiNₓ, SiON, SiCN, HMDSO, etc.

In some embodiments, a device-level encapsulation layer is formed on a tandem solar cell device using a TFE process. A TFE process can be a low temperature process to protect components of the tandem solar cell device (e.g., the active layer (e.g., perovskite layer) of the second solar cell). In some embodiments, the TFE process is performed at a temperature of less than or equal to about 150° C. In some embodiments, the TFE process is performed at a temperature of less than or equal to about 100° C.

In some embodiments, the at least one tandem solar cell device includes a plurality of tandem solar cell devices. After the device-level encapsulation, the plurality of tandem solar cell devices can be formed within a module. In some embodiments, forming the at least one encapsulation layer on the at least one tandem solar cell device further includes performing module-level encapsulation by forming at least one module-level encapsulation layer on the module. The module-level encapsulation layer can be formed in the same processing chamber as the device-level encapsulation layer, or a different processing chamber than the device-level encapsulation layer. In some embodiments, forming the at least one module-level encapsulation layer includes forming an encapsulant over the plurality of tandem solar cell devices. In some embodiments, the encapsulant can include a polymer material. For example, the polymer material can include EVA, PIB, butyl rubber, an epoxy resin, etc. In some embodiments, forming the at least one module-level encapsulation layer further includes forming a pair of glass layers over the encapsulant, where the encapsulant and plurality of tandem solar cell devices are disposed between the pair of glass layers. In some embodiments, the pair of glass layers include tempered glass. Further details regarding operations 1010A-1020A are described above with reference to FIGS. 1-9 and will now be described below with reference to FIG. 10B.

FIG. 10B is a flowchart of a method 1000B for fabricating tandem solar cell devices to reduce active layer damage, in accordance with some embodiments. More specifically, FIG. 10B illustrates the fabrication of a tandem solar cell device using device-level encapsulation. Method 1000B can be performed by a system including a processing chamber communicable coupled to a controller that can include hardware (e.g., processing device, circuitry, dedicated logic, programmable logic, microcode, hardware of a device, integrated circuit, etc.), software (e.g., instructions run or executed on a processing device), or a combination thereof. In some implementations, method 1000B is performed by one or more components of system 900 of FIG. 9. Although shown in a particular sequence or order, unless otherwise specified, the order of the processes can be modified. Thus, the illustrated implementations should be understood only as examples, and the illustrated processes can be performed in a different order, and some processes can be performed in parallel. Additionally, one or more processes can be omitted in various implementations. Thus, not all processes are required in every implementation. Other process flows are possible.

At operation 1010B, a plurality of tandem solar cell devices corresponding to a module is received. For example, at least a portion of at least one tandem solar cell device of the plurality of tandem solar cell devices can be formed using an LDSD process, as described above with reference to FIGS. 1-7I. For example, the plurality of tandem solar cell devices can be placed within a tray and placed within a processing chamber. In some embodiments, a robot apparatus places the plurality of tandem solar cells in the processing chamber. In some embodiments, the processing chamber is a CVD chamber and the tray is a CVD tray. Further details regarding the plurality of tandem solar cell devices are described above with reference to FIGS. 1-8D.

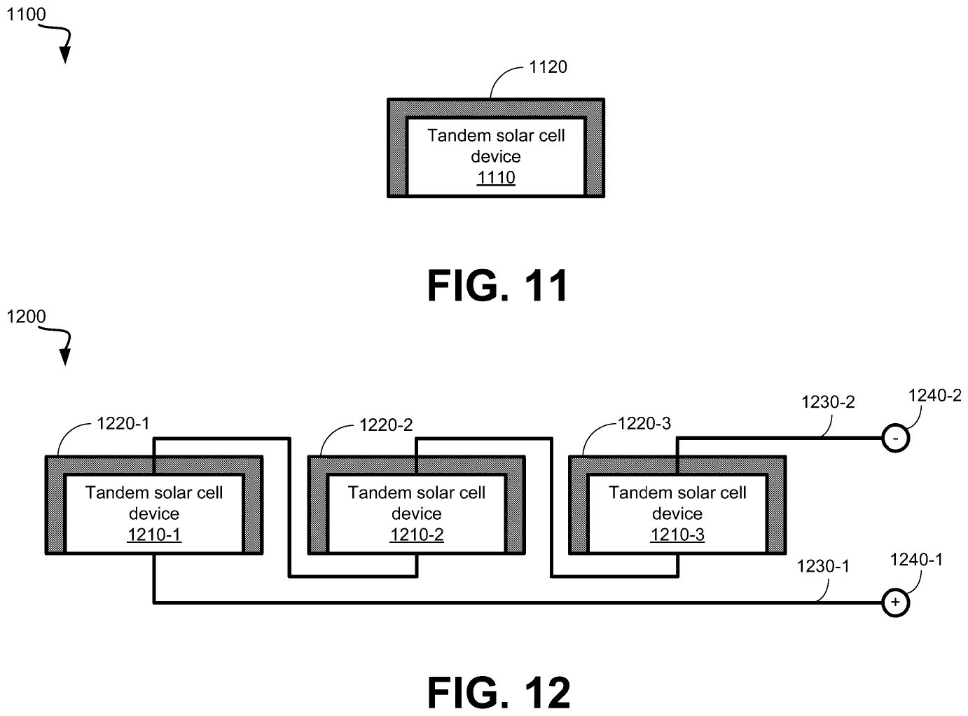

At operation 1020B, a deposition process to form, on each tandem solar cell device, a respective device-level encapsulation layer is initiated and, at operation 1030B, the deposition process is performed. For example, a controller communicably coupled to the processing chamber can initiate the deposition process. In some embodiments, the deposition process is a TFE process. For example, the TFE process can be similar to the TFE process described above with reference to FIG. 10A. At operation 1040B, fabrication of the module is completed. For example, completing fabrication of the module include forming electrical connections to connect each tandem solar cell to a pair of terminals. As another example, completing fabrication of the module can include performing module-level encapsulation, similar to that described above with reference to FIG. 10A. Further details regarding operations 1010B-1040B are described above with reference to FIGS. 1-8A and will now be described below with reference to FIGS. 11-13.

FIG. 11 is a block diagram of an example device 1100 with device-level encapsulation, in accordance with some embodiments. For example, device 1100 can be formed using method 1000A and/or method 1000B, as described above with reference to FIGS. 10A and 10B. As shown, device 100 includes tandem solar cell device 110. In some embodiments, at least a portion of tandem solar cell device 110 is formed using an LDSD process, as described above with reference to FIGS. 1-6B. Tandem solar cell device 1110 can include at least a first solar cell and a second solar cell. In some embodiments, tandem solar cell device 1110 is a two-cell device. For example, the first solar cell can be a bottom solar cell and the second solar cell can be a top solar cell. In some embodiments, a recombination layer is disposed between the first solar cell and the second solar cell. In some embodiments, the first solar cell includes a stack of alternating semiconductor layers. In some embodiments, the first solar cell is an HJT solar cell. In some embodiments, the second solar cell includes a stack of layers including an ETL disposed on an active layer. In some embodiments, the second solar cell is a perovskite solar cell and the active layer is a perovskite layer. In some embodiments, tandem solar cell device 1110 is a triple cell device including a first solar cell, a second solar cell and a third solar cell.

As further shown, device 1100 further includes encapsulation layer 1120. Encapsulation layer 1120 is a device-level encapsulation layer that can be used to protect components of tandem solar cell device 1110 including the active layer (e.g., perovskite layer) of the second solar cell from moisture and/or air conditions. Encapsulation layer 1120 is a discrete encapsulation layer formed on tandem solar cell device 1110. More specifically, encapsulation layer 1120 is a discrete encapsulation layer formed along an upper surface and side surfaces of tandem solar cell device 1110. For example, as shown, encapsulation layer 1120 is a layer of encapsulation material that is conformally deposited along the upper and side surfaces of tandem solar cell device 1110. For example, as shown, encapsulation layer 1120 can be conformally deposited along the upper and side surfaces of tandem solar cell device 1110.

Encapsulation layer 1120 can be formed from a material that provides a suitably low WVTR to protect the active layer from moisture. In some embodiments, encapsulation layer 1120 provides a WVTR that is greater than 10⁻³ g/m²/day. Examples of materials that can be used to form encapsulation layer 120 include Al₂O₃, SiNₓ, SiON, SiCN, HMDSO, etc. In some embodiments, encapsulation layer 120 is formed using TFE. TFE can be performed to form encapsulation layer 120 using any suitable deposition process. In some embodiments, TFE is performed using CVD. Further details regarding fabricating device 1100 are described above with reference to FIGS. 1-10B.

FIG. 12 is a block diagram of an example module 1200 of tandem solar cells with device-level encapsulation, in accordance with some embodiments. As shown, module 1200 can include a plurality of tandem solar cell devices including tandem solar cell devices 1210-1 through 1210-3, and a plurality of encapsulation layers including encapsulation layers 1220-1 through 1220-3 formed on respective ones of tandem solar cell devices 1210-2 through 1210-3. For example, each of tandem solar cell devices 1210-1 through 1210-3 can be similar to tandem solar cell device 1110 of FIG. 11, and each of encapsulation layers 1220-1 through 1220-3 can be a device-level encapsulation layer similar to encapsulation layer 1120 of FIG. 11. In this illustrative example, module 1200 includes three tandem solar cell devices. However, module 1200 can include any suitable number of tandem solar cell devices in accordance with embodiments described herein. As further shown, module 1200 can further include electrical connections among the tandem solar cell devices 1210-1 through 1210-3. In this example, electrical connection 1230-1 can be formed to connect tandem solar cell device 1210-1 to positive terminal 1240-1. Additionally, electrical connection 1230-2 can be formed to connect tandem solar cell devices 1210-1 through 1220-3 to negative terminal 1240-2.

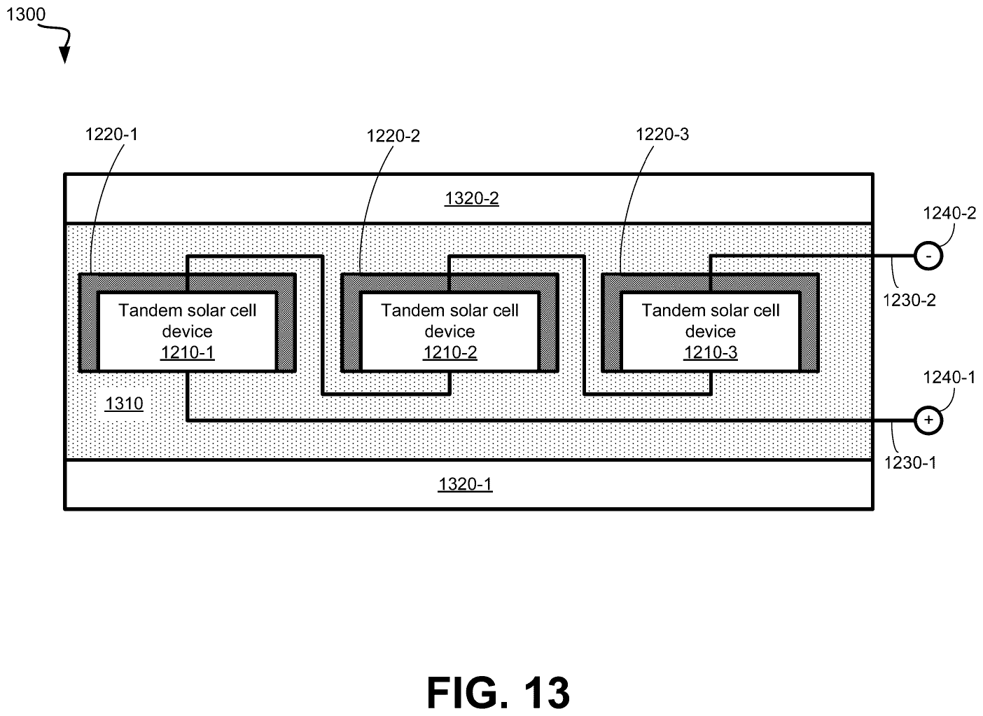

FIG. 13 is a diagram of an example module 1300 of tandem solar cell devices with device-level encapsulation and module-level encapsulation, in accordance with some embodiments. Module 1300 includes tandem solar cells 1210-1 through 1210-3, encapsulation layers 1220-1 through 1220-3, electrical connections 1230-1 and 1230-2, and terminals 1240-1 and 1240-2 as described above with reference to FIG. 12. In addition to the device-level encapsulation provided by encapsulation layers 1220-1 through 1220-3, module 1300 includes module-level encapsulation. More specifically, module 1300 includes encapsulant 1310 and glass layers 1320-1 and 1320-2. In some embodiments, encapsulant 1310 includes a polymer material. For example, the polymer material can include EVA, PIB, butyl rubber, an epoxy resin, etc. In some embodiments, glass layers 1320-1 and 1320-2 include tempered glass.

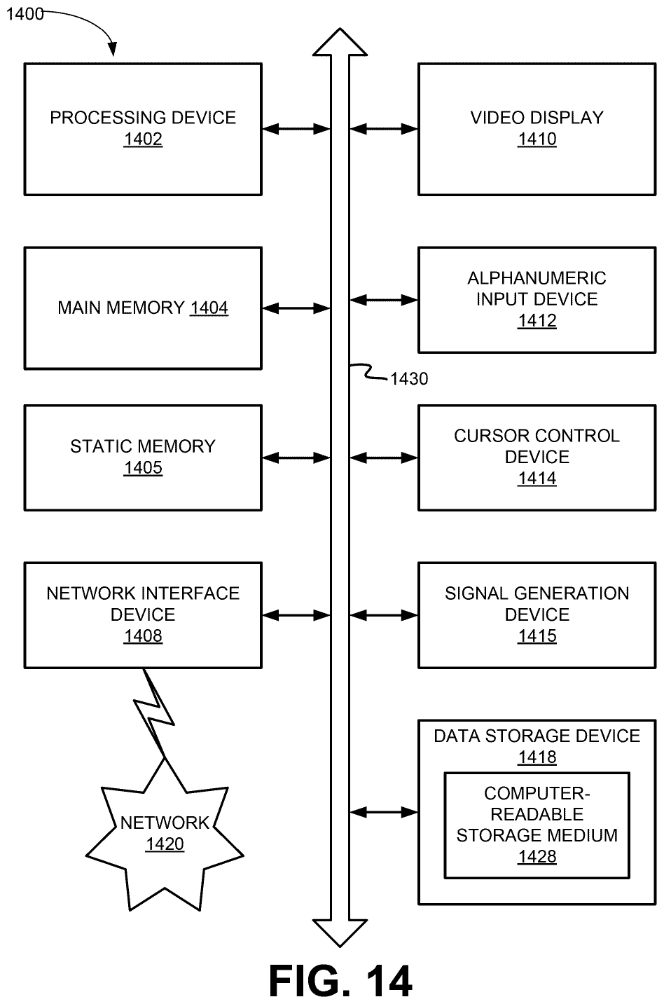

FIG. 14 illustrates a diagrammatic representation of an example computer system 1400, which may be employed for implementing the methods described herein. Computer system 1400 may be connected to other computing devices in a LAN, an intranet, an extranet, and/or the Internet. Computer system 1400 may operate in the capacity of a server machine in a client-server network environment. Computer system 1400 may be provided by a personal computer (PC), a set-top box (STB), a server, a network router, switch or bridge, or any machine capable of executing a set of instructions (sequential or otherwise) that specify actions to be taken by that machine. Further, while only a single computing device is illustrated, the term “computer system” shall also be taken to include any collection of computing devices that individually or jointly execute a set (or multiple sets) of instructions to perform the methods discussed herein. In illustrative examples, computer system 1400 may represent the controller of FIG. 5 and/or FIG. 9.

Computer system 1400 may include processing device 1402, main memory 1404 (e.g., synchronous dynamic random access memory (DRAM), read-only memory (ROM)), and static memory 1405 (e.g., flash memory and data storage device 1418), which may communicate with each other via bus 1430.

Processing device 1402 may be provided by one or more general-purpose processing devices such as a microprocessor, central processing unit, or the like. In an illustrative example, processing device 1402 may comprise a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 1402 may also comprise one or more special-purpose processing devices such as an application specific integrated circuit (ASIC), a field programmable gate array (FPGA), a digital signal processor (DSP), a network processor, or the like. Processing device 1402 may be configured to execute methods of managing computing systems, in accordance with one or more aspects of the present disclosure.

Computer system 1400 may further include network interface device 1408, which may communicate with network 1420. Computer system 1400 also may include a video display unit 1410 (e.g., a liquid crystal display (LCD) or cathode ray tube (CRT)), alphanumeric input device 1412 (e.g., a keyboard), cursor control device 1414 (e.g., a mouse) and/or acoustic signal generation device 1415 (e.g., a speaker). In one embodiment, video display unit 1410, alphanumeric input device 1412, and cursor control device 1414 may be combined into a single component or device (e.g., an LCD touch screen).

Data storage device 1418 may include computer-readable storage medium 1428 on which may be stored one or more sets of instructions (e.g., instructions of the methods of automated review of communications, in accordance with one or more aspects of the present disclosure) implementing any one or more of the methods or functions described herein. The instructions may also reside, completely or at least partially, within main memory 1404 and/or within processing device 1402 during execution thereof by computer system 1400, main memory 1404 and processing device 1402 also constituting computer-readable media. The instructions may further be transmitted or received over a network 1420 via network interface device 1408.

While computer-readable storage medium 1428 is shown in an illustrative example to be a single medium, the term “computer-readable storage medium” shall be taken to include a single medium or multiple media (e.g., a centralized or distributed database and/or associated caches and servers) that store one or more sets of instructions. The term “computer-readable storage medium” shall also be taken to include any medium that is capable of storing, encoding or carrying a set of instructions for execution by the machine and that causes the machine to perform the methods described herein. The term “computer-readable storage medium” shall accordingly be taken to include, but not be limited to, solid-state memories, optical media and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some implementations, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

Embodiments described herein relate using an LDSD process (e.g., an RFTS process) to deposition one or more layers of a solar cell device. Particularly when utilizing AC or bipolar RFTS, materials of a layer stack of the solar cell device, which are not accessible to evaporation can be deposited (and faster as compared to ALD). The deposition with RFTS can reduce or minimize sputter deposition induced damage effects. Further, a solar cell device stack can be simplified, and manufacturing costs can be reduced, by enabling TCO deposition without the need of an additional buffer layer, for example, between the top charge transport layer and an electrode. The RFTS process can enable faster solar cell device development time while optimizing productivity for solar cell device stacks. Larger design freedom in material choices for layers on top of top solar cell can be provided.

According to some embodiments, which can be combined with other embodiments described herein, the position of the solar cell device according to embodiments of the present disclosure may also be provided in a roll-to-roll deposition system, for which material deposition is provided on a flexible substrate unwound from the first role and wound to a second role.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method, comprising:
obtaining a base structure of a tandem solar cell device; and
forming a transparent conductive oxide (TCO) layer on the base structure using a low damage sputter deposition (LDSD) process, wherein the LDSD process comprises a rotatable facing target sputtering (RFTS) process.

2. The method of claim 1, wherein the TCO layer comprises at least one of: indium tin oxide (ITO), indium zinc oxide (IZO), indium cerium oxide (ICO), or aluminum-doped zinc oxide (AZO).

3. The method of claim 1, wherein the base structure comprises a stack of layers of a solar cell comprising an electron transport layer disposed on an active layer.

4. The method of claim 3, wherein the active layer comprises a perovskite layer and the solar cell is a perovskite solar cell.

5. The method of claim 1, wherein the base structure comprises a heterojunction (HJT) solar cell.

6. The method of claim 1, wherein the base structure comprises a first solar cell, and wherein the TCO layer is a recombination layer formed on the first solar cell.

7. The method of claim 6, further comprising forming a second solar cell on the recombination layer, wherein the first solar cell is a heterojunction (HJT) solar cell, and wherein the second solar cell is a perovskite solar cell.

8. The method of claim 1, further comprising forming, using the LDSD process, at least one of:
an electron transport layer (ETL) or a hole transport layer (HTL).

9. The method of claim 1, further comprising:
forming a set of electrodes on the TCO layer; and
forming a device-level encapsulation layer on the tandem solar cell device.

10. The method of claim 9, wherein the device-level encapsulation layer is formed at a temperature of less than or equal to about 150° C.

11. A method, comprising:
receiving a base structure of a solar cell device;
forming a layer on the base structure using a sputter deposition process, wherein forming the layer on the base structure using the sputter deposition process comprises directing first sputter material from a first rotary target with a facing magnet yoke position towards a second rotary target and directing second sputter material from the second rotary target with a facing magnet yoke position towards the first rotary target; and
completing fabrication of the solar cell device.

12. The method of claim 11, wherein the layer is a transparent conductive oxide (TCO) layer, an electron transport layer (ETL), or a hole transport layer (HTL).

13. The method of claim 11, wherein the layer comprises at least one of: indium tin oxide (ITO), indium zinc oxide (IZO), indium cerium oxide (ICO), or aluminum-doped zinc oxide (AZO).

14. The method of claim 11, wherein the base structure comprises a stack of layers of a solar cell comprising an active layer.

15. The method of claim 14, wherein the active layer comprises a perovskite layer and the solar cell is a perovskite solar cell.

16. The method of claim 11, wherein the base structure comprises a heterojunction (HJT) solar cell.

17. The method of claim 11, wherein the base structure comprises a first solar cell, and wherein the layer is a recombination layer formed on the first solar cell.

18. The method of claim 17, wherein completing fabrication of the solar cell device further comprises forming a second solar cell on the recombination layer.

19. The method of claim 18, wherein the first solar cell is a heterojunction (HJT) solar cell, and wherein the second solar cell is a perovskite solar cell.

20. The method of claim 11, wherein the sputter deposition process uses at least one of: alternating current (AC) sputtering, direct current (DC) sputtering, or bipolar sputtering.
